(19) United States
(12) Patent Application Publication
(10) Pub. No.: US 2025/0183870 A1
(43) Pub. Date: Jun. 5, 2025

(54) ACOUSTIC WAVE DEVICE

(71) Applicant: Murata Manufacturing Co., Ltd., Nagaokakyo-shi (JP)

(72) Inventors: Masakazu MIMURA, Nagaokakyo-shi (JP); Sho NAGATOMO, Nagaokakyo-shi (JP); Naohiro NODAKE, Nagaokakyo-shi (JP)

(21) Appl. No.: 19/041,160

(22) Filed: Jan. 30, 2025

Related U.S. Application Data
(63) Continuation of application No. PCT/JP2023/030812, filed on Aug. 25, 2023.
(60) Provisional application No. 63/401,256, filed on Aug. 26, 2022.

(51) Int. Cl. H03H 9/13; H03H 9/02; H03H 9/17; H03H 9/56

(52) U.S. Cl. CPC H03H 9/132; H03H 9/02015; H03H 9/172; H03H 9/568

(57) ABSTRACT

An acoustic wave device includes a piezoelectric film including a piezoelectric layer including a piezoelectric body, one of first and second comb electrodes connected to an input potential and the other of the first and second comb electrodes connected to an output potential. An order in which a first electrode finger, a second electrode finger, and a third electrode finger are arranged side by side is an order in which the first electrode finger, the third electrode finger, the second electrode finger, and the third electrode finger are set as one period when the order is started from the first electrode finger. At least one of a portion of the first comb electrode and a portion of the third electrode, and a portion of the second comb electrode and a portion of the third electrode intersects each other on the piezoelectric layer with the insulator layer interposed therebetween.

### CROSS REFERENCE TO RELATED APPLICATIONS

This application claims the benefit of priority to Provisional Application No. 63/401,256 filed on Aug. 26, 2022 and is a Continuation Application of PCT Application No. PCT/JP2023/030812 filed on Aug. 25, 2023. The entire contents of each application are hereby incorporated herein by reference.

### BACKGROUND OF THE INVENTION

### 1. Field of the Invention

The present invention relates to acoustic wave devices.

### 2. Description of the Related Art

In the related art, an acoustic wave device is widely used as a filter or the like of a mobile phone. In recent years, as described in U.S. Pat. No. 10,491,192, an acoustic wave device using a bulk wave in a thickness shear mode has been proposed. In the acoustic wave device, a piezoelectric layer is provided on a support body. A pair of electrodes are provided on the piezoelectric layer. The pair of electrodes face each other on the piezoelectric layer, and are connected to mutually different potentials. An alternating current (AC) voltage is applied between the electrodes to excite the bulk wave in the thickness shear mode.

### SUMMARY OF THE INVENTION

For example, an acoustic wave device is an acoustic wave resonator, and is used in a ladder filter, for example. In order to obtain satisfactory characteristics in the ladder filter, it is necessary to increase an electrostatic capacitance ratio between a plurality of the acoustic wave resonators. In this case, it is necessary to increase an electrostatic capacitance of some acoustic wave resonators in the ladder filter.

In order to increase the electrostatic capacitance of the acoustic wave resonator, for example, it is necessary to increase a size of the acoustic wave resonator. Therefore, when the acoustic wave resonator is used in the ladder filter, a size of the ladder filter tends to increase. In particular, the size of the ladder filter having the acoustic wave resonator using a bulk wave in a thickness shear mode with small electrostatic capacitance increases.

The present inventors have discovered that, in a case where a configuration of the acoustic wave device has the following configuration, a suitable filter waveform can be obtained without increasing the size of the acoustic wave device in a case where the acoustic wave device is used in a filter device. The configuration includes an electrode connected to a reference potential or the like, which is a potential different from an input potential and an output potential, and between an electrode connected to the input potential and an electrode connected to the output potential.

Meanwhile, the present inventors have also discovered that, in the configuration described above, there is a large restriction on a layout of the electrode connected to the reference potential or the like, a width of the electrode is likely to be narrow, and a length of the electrode to be routed is likely to be long. In this case, an electrical resistance of the electrode connected to the reference potential or the like is likely to be high, and a potential of the electrode is likely to be unstable. Therefore, in a case of being used in a filter device, there is a concern that filter characteristics of the filter device may deteriorate.

Example embodiments of the present invention provide acoustic wave devices each capable of achieving a reduction in size of a filter device and reducing an electrical resistance of an electrode connected to a potential other than an input potential and an output potential.

According to an example embodiment of the present invention, an acoustic wave device includes a piezoelectric film that includes a piezoelectric layer including a piezoelectric body, a first comb-shaped electrode that is provided on the piezoelectric layer and includes a first busbar and a plurality of first electrode fingers each including one end connected to the first busbar, a second comb-shaped electrode that is provided on the piezoelectric layer and includes a second busbar and a plurality of second electrode fingers each including one end connected to the second busbar and interdigitated with the plurality of first electrode fingers, a third electrode that includes a plurality of third electrode fingers each provided on the piezoelectric layer to be arranged side by side with the first electrode fingers and the second electrode fingers, in plan view in a direction in which the first electrode fingers and the second electrode fingers are arranged side by side, and at least one third busbar which connects the third electrode fingers adjacent to each other, the third electrode being connected to a potential different from a potential of the first comb-shaped electrode and a potential of the second comb-shaped electrode, and an insulator layer that is provided on the piezoelectric layer, in which one of the first comb-shaped electrode and the second comb-shaped electrode is connected to an input potential, and the other of the first comb-shaped electrode and the second comb-shaped electrode is connected to an output potential, an order in which a first electrode finger among the first electrode fingers, a second electrode finger among the second electrode fingers, and a third electrode finger among the third electrode fingers are arranged side by side is an order in which the first electrode finger, the third electrode finger, the second electrode finger, and the third electrode finger are set as one period in a case where the order is started from the first electrode finger, and at least one of a portion of the first comb-shaped electrode and a portion of the third electrode, and a portion of the second comb-shaped electrode and a portion of the third electrode intersect each other on the piezoelectric layer with the insulator layer interposed therebetween.

According to example embodiments of the present invention, it is possible to provide acoustic wave devices each capable of achieving a reduction in size of a filter device and reducing an electrical resistance of an electrode connected to a potential other than an input potential and an output potential.

The above other and elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view of an acoustic wave device according to a first example embodiment of the present invention.

FIG. 2 is a schematic plan view of the acoustic wave device according to the first example embodiment of the present invention.

FIG. 3 is a schematic cross-sectional view taken along a line II-II in FIG. 2.

FIG. 4 is a view illustrating a bandpass characteristic and a reflection characteristic of the acoustic wave device according to the first example embodiment of the present invention.

FIG. 5 is a schematic plan view of an acoustic wave device of a reference example.

FIG. 6 is a view illustrating a map of a fractional bandwidth with respect to Euler angles (0°, θ, ψ) of LiNbO₃ in a case where d/p is infinitely close to 0.

FIG. 7 is a schematic elevational cross-sectional view illustrating a vicinity of a portion at which a third busbar is laminated with an insulator layer and a first electrode finger, in a modification example of the first example embodiment of the present invention.

FIG. 8 is a schematic plan view of an acoustic wave device according to a second example embodiment of the present invention.

FIG. 9 is a schematic elevational cross-sectional view illustrating a vicinity of a portion at which a first busbar is laminated with an insulator layer and a third electrode finger, in the second example embodiment of the present invention.

FIG. 10 is a schematic elevational cross-sectional view illustrating a vicinity of a portion at which a first busbar is laminated with an insulator layer and a third electrode finger, in a modification example of the second example embodiment of the present invention.

FIG. 11 is a schematic plan view of an acoustic wave device according to a third example embodiment of the present invention.

FIG. 12 is a schematic plan view of an acoustic wave device according to a fourth example embodiment of the present invention.

FIG. 13 is a schematic plan view of an acoustic wave device according to a first modification example of the fourth example embodiment of the present invention.

FIG. 14 is a schematic plan view of an acoustic wave device according to a second modification example of the fourth example embodiment of the present invention.

FIG. 15 is a schematic plan view of an acoustic wave device according to a third modification example of the fourth example embodiment of the present invention.

FIG. 16 is a schematic cross-sectional view of a third busbar in a direction orthogonal to a direction in which the third busbar extends, in a fifth example embodiment of the present invention.

FIG. 17 is a schematic cross-sectional view of a third busbar in a direction orthogonal to a direction in which the third busbar extends, in a sixth example embodiment of the present invention.

FIG. 18 is a schematic plan view illustrating a portion of a functional electrode, in a seventh example embodiment of the present invention.

FIG. 19 is a schematic plan view of an acoustic wave device according to an eighth example embodiment of the present invention.

FIG. 20 is a schematic elevational cross-sectional view illustrating a vicinity of a portion between two locations at which a third busbar is laminated with an insulator layer and a first electrode finger, in a modification example of the eighth example embodiment of the present invention.

FIGS. 21A to 21C are schematic plan views for describing an example of a method for manufacturing the acoustic wave device according to the eighth example embodiment of the present invention.

FIGS. 22A to 22D are views illustrating an example of a method for manufacturing the acoustic wave device according to the modification example of the eighth example embodiment of the present invention.

FIG. 23A is a schematic perspective view illustrating an appearance of an acoustic wave device using a bulk wave in a thickness shear mode, and FIG. 23B is a plan view illustrating an electrode structure on a piezoelectric layer.

FIG. 24 is a cross-sectional view of a portion taken along a line A-A in FIG. 23A.

FIG. 25A is a schematic elevational cross-sectional view for describing a Lamb wave that propagates through a piezoelectric film of the acoustic wave device, and FIG. 25B is a schematic elevational cross-sectional view for describing a bulk wave in a thickness shear mode, which propagates through the piezoelectric film of the acoustic wave device.

FIG. 26 is a view illustrating an amplitude direction of the bulk wave in the thickness shear mode.

FIG. 27 is a view illustrating resonance characteristics of the acoustic wave device using the bulk wave in the thickness shear mode.

FIG. 28 is a view illustrating a relationship between d/p and a fractional bandwidth as a resonator in a case where a center-to-center distance of electrodes adjacent to each other is defined as p and a thickness of a piezoelectric layer is defined as d.

FIG. 29 is a plan view of the acoustic wave device using the bulk wave in the thickness shear mode.

FIG. 30 is a view illustrating resonance characteristics of an acoustic wave device of a reference example in which spurious appears.

FIG. 31 is a view illustrating a relationship between a fractional bandwidth and a phase rotation amount of an impedance of the spurious standardized at 180 degrees as a magnitude of the spurious.

FIG. 32 is a view illustrating a relationship between d/2p and a metallization ratio MR.

FIG. 33 is a view illustrating the map of the fractional bandwidth with respect to Euler angles (0°, θ, ψ) of LiNbO₃ in a case where d/p is infinitely close to 0.

FIG. 34 is an elevational cross-sectional view of an acoustic wave device having an acoustic multilayer film.

FIG. 35 is a perspective view of a partial notch for describing an acoustic wave device using the Lamb wave.

### DETAILED DESCRIPTION OF THE EXAMPLE EMBODIMENTS

Hereinafter, the present invention will be elucidated by describing specific example embodiments of the present invention with reference to the drawings.

Each example embodiment described in the present specification is merely an example, and configurations can be partially replaced or combined with each other between different example embodiments.

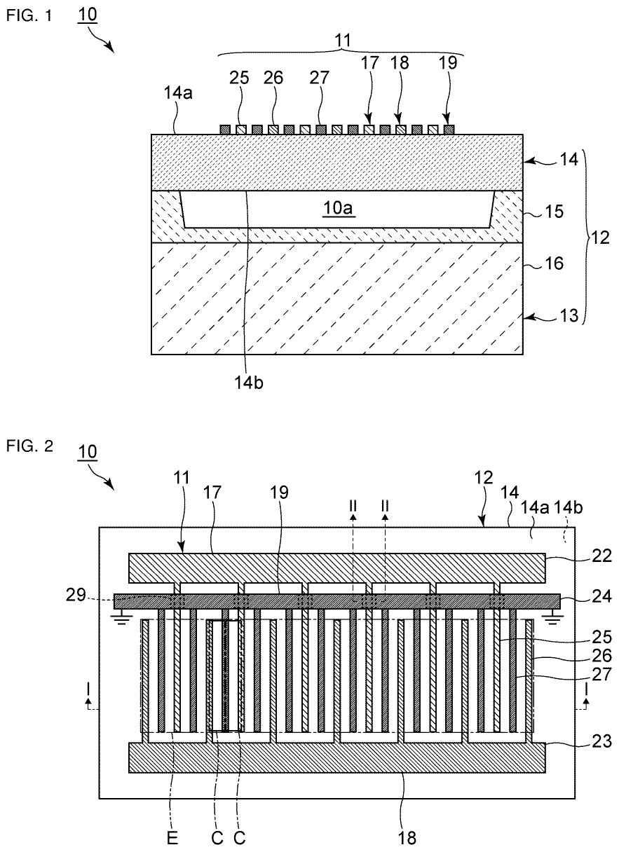

FIG. 1 is a schematic elevational cross-sectional view of an acoustic wave device according to a first example embodiment of the present invention. FIG. 2 is a schematic plan view of the acoustic wave device according to the first example embodiment. FIG. 1 is a schematic cross-sectional view taken along a line I-I in FIG. 2. In FIG. 2, each electrode is illustrated with hatching. In FIG. 2, a symbol of a reference potential schematically illustrates that a third electrode to be described below is connected to the reference potential. In a schematic plan view other than FIG. 2, in the same manner, hatching may be added to an electrode, and a symbol of a reference potential may be used.

An acoustic wave device 10 illustrated in FIG. 1 is configured such that a thickness shear mode can be used. The acoustic wave device 10 is an acoustic coupling type filter. Hereinafter, a configuration of the acoustic wave device 10 will be described.

The acoustic wave device 10 includes a piezoelectric substrate 12 and a functional electrode 11. The piezoelectric substrate 12 is a substrate having piezoelectricity. Specifically, the piezoelectric substrate 12 includes a support 13 and a piezoelectric layer 14 as a piezoelectric film. The piezoelectric layer 14 is a layer including a piezoelectric body. On the other hand, in the present specification, the piezoelectric film is a film having piezoelectricity, and does not necessarily refer to a film including a piezoelectric body. Meanwhile, in the present example embodiment, the piezoelectric film is a single-layer piezoelectric layer 14, and is a film including a piezoelectric body. In the present invention, the piezoelectric film may be a laminated film including the piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. The present invention is not limited to the configuration described above, and the support 13 may be configured with only the support substrate 16. Alternatively, the support 13 is not necessarily be provided.

The piezoelectric layer 14 includes a first main surface 14a and a second main surface 14b. The first main surface 14a and the second main surface 14b face each other. Out of the first main surface 14a and the second main surface 14b, the second main surface 14b is located on the support 13 side. The functional electrode 11 is provided on the first main surface 14a.

The functional electrode 11 has a pair of comb-shaped electrodes and a third electrode 19. Specifically, the pair of comb-shaped electrodes are the first comb-shaped electrode 17 and the second comb-shaped electrode 18. The first comb-shaped electrode 17 is connected to an input potential. The second comb-shaped electrode 18 is connected to an output potential. In the present example embodiment, the third electrode 19 is connected to a reference potential. In the present example embodiment, the third electrode 19 is a reference potential electrode.

The first comb-shaped electrode 17 may be connected to the output potential. The second comb-shaped electrode 18 may be connected to the input potential. In this manner, the first comb-shaped electrode 17 may be connected to one of the input potential and the output potential. The second comb-shaped electrode 18 may be connected to the other potential of the input potential and the output potential.

The third electrode 19 is not necessarily be connected to the reference potential. The third electrode 19 may be connected to a potential different from the first comb-shaped electrode 17 and the second comb-shaped electrode 18. Meanwhile, it is preferable that the third electrode 19 is connected to the reference potential.

The first comb-shaped electrode 17 and the second comb-shaped electrode 18 are provided on the first main surface 14a of the piezoelectric layer 14. The first comb-shaped electrode 17 includes a first busbar 22 and a plurality of first electrode fingers 25. Each one end of the plurality of first electrode fingers 25 is connected to the first busbar 22. The second comb-shaped electrode 18 includes a second busbar 23 and a plurality of second electrode fingers 26. Each one end of the plurality of second electrode fingers 26 is connected to the second busbar 23. The first busbar 22 and the second busbar 23 face each other. The plurality of first electrode fingers 25 and the plurality of second electrode fingers 26 are interdigitated with each other. The first electrode finger 25 and the second electrode finger 26 are alternately arranged side by side in a direction orthogonal to a direction in which the first electrode fingers 25 and the second electrode fingers 26 extend.

The third electrode 19 includes one third busbar 24 and a plurality of third electrode fingers 27. The plurality of third electrode fingers 27 are provided on the first main surface 14a of the piezoelectric layer 14. The plurality of third electrode fingers 27 are electrically connected to each other by the third busbar 24.

Each of the plurality of third electrode fingers 27 is provided to be arranged side by side with the first electrode fingers 25 and the second electrode fingers 26 in a direction in which the first electrode fingers 25 and the second electrode fingers 26 are arranged side by side. Accordingly, the first electrode fingers 25, the second electrode fingers 26, and the third electrode fingers 27 are arranged side by side in one direction. The plurality of third electrode fingers 27 extend in parallel with the plurality of first electrode fingers 25 and the plurality of second electrode fingers.

In the following, a direction in which the first electrode finger 25, the second electrode finger 26, and the third electrode finger 27 extend is referred to as an electrode finger extending direction, and a direction orthogonal to the electrode finger extending direction is referred to as an electrode finger orthogonal direction. When a direction in which the first electrode fingers 25, the second electrode fingers 26, and the third electrode fingers 27 are arranged side by side is defined as an electrode finger arrangement direction, the electrode finger arrangement direction is parallel to the electrode finger orthogonal direction. In the present example embodiment, the electrode finger arrangement direction is also parallel to a direction in which the first busbar 22, the second busbar 23, and the third busbar 24 extend. In the present specification, the first electrode finger 25, the second electrode finger 26, and the third electrode finger 27 may be collectively and simply referred to as electrode fingers. The first busbar 22, the second busbar 23, and the third busbar 24 may be collectively and simply referred to as a busbar.

An order in which the plurality of electrode fingers are arranged side by side is an order in which the first electrode finger 25, the third electrode finger 27, the second electrode finger 26, and the third electrode finger 27 are set as one period in a case where the order is started from the first electrode finger 25. Therefore, the order in which the plurality of electrode fingers are arranged side by side is continued as the first electrode finger 25, the third electrode finger 27, the second electrode finger 26, the third electrode finger 27, the first electrode finger 25, the third electrode finger 27, the second electrode finger 26, or the like. In a case where the input potential is represented by IN, the output potential is represented by OUT, and the reference potential is represented by GND, and the order of the plurality of electrode fingers is represented by an order of the potentials to be connected, the order is continued as IN, GND, OUT, GND, IN, GND, OUT, or the like.

In the present example embodiment, in a region in which the plurality of electrode fingers are provided, electrode fingers located at both end portions in the electrode finger orthogonal direction are all the second electrode fingers 26. In the region, the electrode finger located at the end portion in the electrode finger orthogonal direction may be any type of electrode finger among the first electrode finger 25, the second electrode finger 26, and the third electrode finger 27.

In the functional electrode 11, the configuration excluding the third electrode 19 is the same as the configuration of an interdigital transducer (IDT) electrode. A region in which the first electrode fingers 25 and the second electrode fingers 26 adjacent to each other overlap with each other when viewed from the electrode finger orthogonal direction is an intersecting region E. Meanwhile, the intersecting region E can also be said to be a region in which the first electrode finger 25 and the third electrode finger 27 adjacent to each other or the second electrode finger 26 and the third electrode fingers 27 adjacent to each other overlap with each other when viewed from the electrode finger orthogonal direction.

As illustrated in FIG. 2, the third busbar 24 of the third electrode 19 electrically connects the plurality of third electrode fingers 27. Specifically, the third busbar 24 is located in a region between the intersecting region E and the first busbar 22. The plurality of first electrode fingers 25 are also located in this region. Meanwhile, the third busbar 24 and the plurality of first electrode fingers 25 are electrically insulated from each other by a plurality of insulator layers 29.

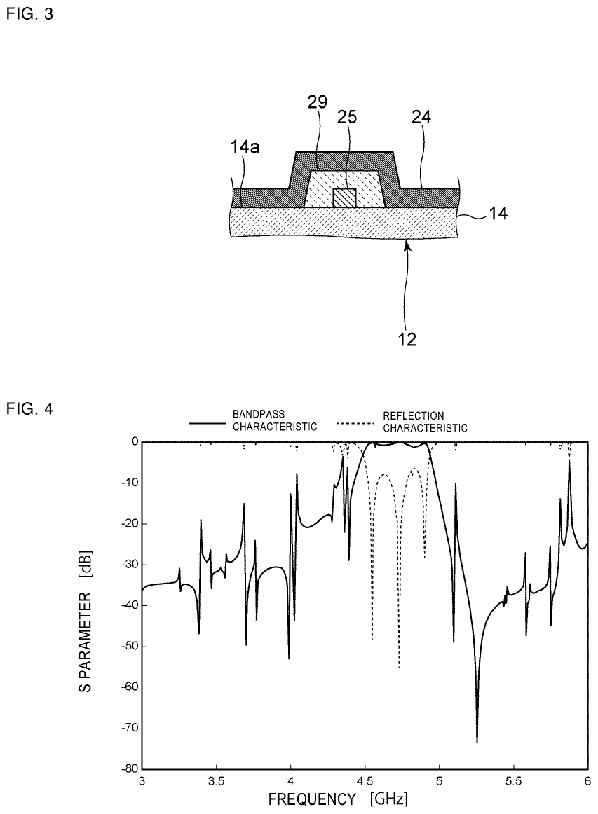

FIG. 3 is a schematic cross-sectional view taken along a line II-II in FIG. 2.

The insulator layer 29 is provided on the first main surface 14a of the piezoelectric layer 14 to cover the first electrode fingers 25. More specifically, in the present example embodiment, one insulator layer 29 covers a portion of one first electrode finger 25 in the electrode finger extending direction.

As illustrated in FIG. 2, the plurality of the insulator layers 29 are arranged side by side in the electrode finger orthogonal direction. Each of the insulator layers 29 is provided to cover a portion of one first electrode finger 25. On the other hand, the plurality of third electrode fingers 27 are not covered with the insulator layer 29. The third busbar 24 is provided on the first main surface 14a, on the plurality of insulator layers 29, and on the plurality of third electrode fingers 27.

In this manner, the plurality of first electrode fingers 25 that are portions of the first comb-shaped electrode 17 and the third busbar 24 that is a portion of the third electrode 19 intersect each other on the piezoelectric layer 14 with the insulator layer 29 interposed therebetween. Therefore, the third busbar 24 and the plurality of first electrode fingers 25 are electrically insulated from each other. On the other hand, the third busbar 24 electrically connects the plurality of third electrode fingers 27. A material of the third busbar 24 and a material of the third electrode finger 27 are the same. Meanwhile, the material of the third busbar 24 and the material of the third electrode finger 27 may be different from each other.

In the present example embodiment, the third busbar 24 is located in a region between the intersecting region E and the first busbar 22. In other words, the third busbar 24 is located in a region between tips of the plurality of second electrode fingers 26 and the first busbar 22. Therefore, each of the tips of the plurality of second electrode fingers 26 faces the third busbar 24 with a gap therebetween, in the electrode finger extending direction. On the other hand, each of tips of the plurality of first electrode fingers 25 faces the second busbar 23 with a gap therebetween, in the electrode finger extending direction.

The third busbar 24 may be located in a region between the tips of the plurality of first electrode fingers 25 and the second busbar 23. In this case, each of the tips of the plurality of first electrode fingers 25 faces the third busbar 24 with a gap therebetween. On the other hand, each of the tips of the plurality of second electrode fingers 26 faces the first busbar 22 with a gap therebetween.

As described above, in a case where the third electrode 19 is a reference potential electrode, the acoustic wave device 10 may be configured as follows. Each of the tips of the plurality of first electrode fingers 25 may face an electrode connected to a potential, which is a potential different from the electrode finger and is any of the input potential, the output potential, or the reference potential, with a gap therebetween, in the electrode finger extending direction. In the same manner, each of the tips of the plurality of second electrode fingers 26 may face an electrode connected to a potential, which is a potential different from the electrode finger and is any of the input potential, the output potential, and the reference potential, with a gap therebetween, in the electrode finger extending direction.

The acoustic wave device 10 is an acoustic wave resonator configured to use a bulk wave in a thickness shear mode. As illustrated in FIG. 2, the acoustic wave device 10 includes a plurality of excitation regions C. In the plurality of excitation regions C, a bulk wave in a thickness shear mode or an acoustic wave in other modes is excited. In FIG. 2, only two excitation regions C among the plurality of excitation regions C are illustrated.

A plurality of excitation regions C among all the excitation regions C are each a region in which the first electrode finger 25 and the third electrode finger 27 adjacent to each other overlap with each other and is a region between centers of the first electrode finger 25 and the third electrode finger 27 adjacent to each other, when viewed from the electrode finger orthogonal direction. A plurality of remaining excitation regions C are each a region in which the second electrode finger 26 and the third electrode finger 27 adjacent to each other overlap with each other and a region between centers of the second electrode finger 26 and the third electrode finger 27 adjacent to each other, when viewed from the electrode finger orthogonal direction. These excitation regions C are arranged side by side in the electrode finger orthogonal direction. The plurality of excitation regions C are included in the intersecting region E. The intersecting region E and the excitation region C are regions of the piezoelectric layer 14, which are defined based on the configuration of the functional electrode 11.

Unique features of the present example embodiment are as follows. 1) The third electrode finger 27 of the third electrode 19 is located between the first electrode finger 25 of the first comb-shaped electrode 17 and the second electrode finger 26 of the second comb-shaped electrode 18. 2) The plurality of first electrode fingers 25 that are portions of the first comb-shaped electrode 17 and the third busbar 24 that is a portion of the third electrode 19 intersect each other on the piezoelectric layer 14 with the insulator layer 29 interposed therebetween. Accordingly, in a case where the acoustic wave device 10 is used in a filter device, the filter device can be further reduced in size. In addition, an electrical resistance of the third electrode 19 connected to a potential other than the input potential and the output potential can be reduced. These will be described below.

FIG. 4 illustrates an example of a bandpass characteristic and a reflection characteristic of the acoustic wave device 10.

FIG. 4 is a view illustrating a bandpass characteristic and a reflection characteristic of the acoustic wave device according to the first example embodiment. FIG. 4 illustrates a result of a finite element method (FEM) simulation.

As illustrated in FIG. 4, it can be understood that a filter waveform can be suitably obtained even with one acoustic wave device 10. The acoustic wave device 10 is an acoustic coupling type filter. More specifically, as illustrated in FIG. 2, the acoustic wave device 10 has the excitation region C located between the centers of the first electrode finger 25 and the third electrode finger 27 adjacent to each other and the excitation region C located between the centers of the second electrode finger 26 and the third electrode fingers 27 adjacent to each other. In these excitation regions C, acoustic waves of a plurality of modes including a bulk wave in a thickness shear mode are excited. By coupling these modes, a filter waveform can be suitably obtained even with one acoustic wave device 10.

In a case where the acoustic wave device 10 is used as an acoustic wave resonator in a filter device, a filter waveform can be suitably obtained even with one or a small number of acoustic wave resonators of the filter device. Therefore, it is possible to achieve a reduction in size of the filter device.

In addition, as illustrated in FIGS. 2 and 3, in the present example embodiment, the portion of the first comb-shaped electrode 17 and the portion of the third electrode 19 intersect each other with the insulator layer 29 interposed therebetween. Therefore, a length of the third electrode 19 can be shortened.

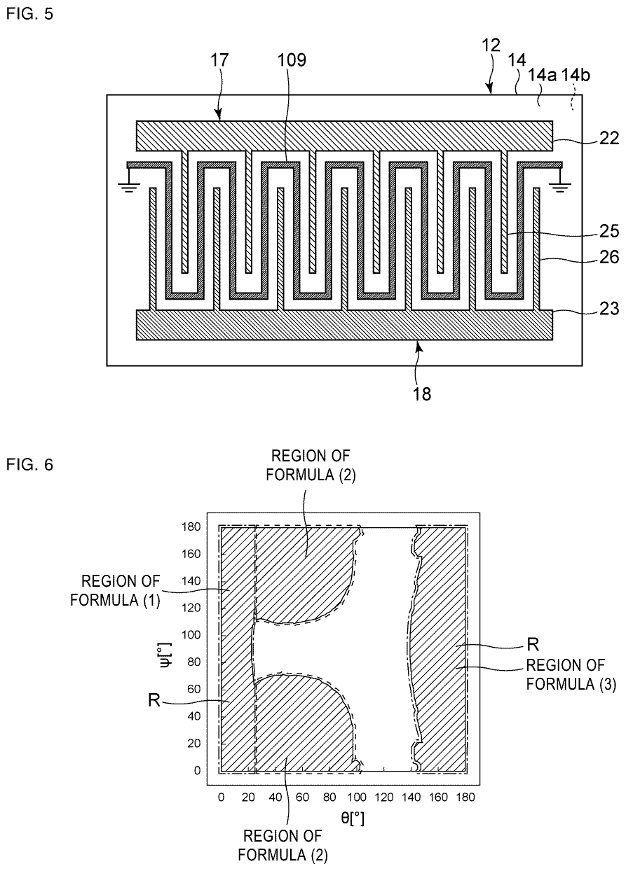

More specifically, for example, in a reference example illustrated in FIG. 5, a third electrode 109 has a meandering shape. Specifically, the third electrode 109 has a plurality of portions corresponding to the third electrode fingers. One ends or the other ends of these portions are connected, and thus the third electrode 109 has the meandering shape. Therefore, an overall length of the third electrode 109 is long.

As schematically illustrated in FIG. 5, the third electrode 109 is connected to a reference potential with a terminal electrically connected to an outside, the terminal being interposed therebetween. In the third electrode 109, the plurality of portions corresponding to the third electrode fingers are included between a portion corresponding to the third electrode finger located near a center and the terminal. Therefore, a length of the third electrode 109 from the portion corresponding to the third electrode finger located near the center to a portion connected to the terminal is particularly long.

On the other hand, in the present example embodiment illustrated in FIG. 2, one end of each third electrode finger 27 is connected to the third busbar 24. Then, the third busbar 24 is connected to a terminal that is electrically connected to an outside. Therefore, regardless of a position of the third electrode finger 27, a length of the third electrode 19 from the third electrode finger 27 to a portion of the third electrode 19, which is connected to the terminal, can be reduced. Therefore, an electrical resistance of the third electrode 19 can be reduced.

In this case, a stability of a potential of the third electrode 19 can be increased. As a result, in a case where the acoustic wave device 10 is used in a filter device, deterioration of filter characteristics of the filter device can be reduced or prevented.

As illustrated in FIG. 2, it is preferable that a width of the third busbar 24 is larger than a width of the third electrode finger 27. As a result, the electrical resistance of the third electrode 19 can be effectively reduced. A width of a busbar is a dimension of the busbar, in a direction orthogonal to a direction in which the busbar extends. A width of an electrode finger is a dimension of the electrode finger, in the electrode finger orthogonal direction.

Hereinafter, configurations of the present example embodiment will be described in more detail.

As illustrated in FIG. 1, the support 13 includes the support substrate 16 and the insulating layer 15. The piezoelectric substrate 12 is a multilayer body of the support substrate 16, the insulating layer 15, and the piezoelectric layer 14. That is, the piezoelectric layer 14 and the support 13 overlap with each other when viewed in a direction in which the first main surface 14a and the second main surface 14b of the piezoelectric layer 14 face each other.

As a material of the support substrate 16, for example, a semiconductor such as silicon, ceramics such as aluminum oxide, or the like can be used. As a material of the insulating layer 15, an appropriate dielectric such as silicon oxide or tantalum oxide can be used. For example, the piezoelectric layer 14 is a lithium niobate layer such as a LiNbO₃ layer, or a lithium tantalate layer such as a LiTaO₃ layer.

The insulating layer 15 is provided with a recess portion. The piezoelectric layer 14 as a piezoelectric film is provided on the insulating layer 15 to cover the recess portion. Therefore, a hollow portion is provided. The hollow portion includes a cavity portion 10a. In the present example embodiment, the support 13 and the piezoelectric film are positioned such that a portion of the support 13 and a portion of the piezoelectric film face each other with the cavity portion 10a interposed therebetween. Meanwhile, the recess portion at the support 13 may be provided over the insulating layer 15 and the support substrate 16. Alternatively, the recess portion provided only at the support substrate 16 may be closed by the insulating layer 15. The recess portion may be provided at the piezoelectric layer 14, for example. The cavity portion 10a may include a through-hole provided in the support 13.

The cavity portion 10a is an acoustic reflection portion in an example embodiment of the present invention. The acoustic reflection portion can effectively confine energy of an acoustic wave on the piezoelectric layer 14 side. The acoustic reflection portion may be provided at a position that overlaps with at least a portion of the functional electrode 11 in the support 13, in plan view. More specifically, in plan view, at least a portion of each of the first electrode finger 25, the second electrode finger 26, and the third electrode finger 27 may overlap with the acoustic reflection portion. It is preferable that the plurality of excitation regions C overlap with the acoustic reflection portion, in plan view.

In the present specification, the description of “in plan view” means that an object is viewed in a lamination direction of the support 13 and the piezoelectric film from a direction corresponding to an upward direction in FIG. 1. In FIG. 1, for example, the piezoelectric layer 14 side is an upper side out of the support substrate 16 side and the piezoelectric layer 14 side. Further, in the present specification, the plan view is synonymous with a view from a main surface facing direction. The main surface facing direction is a direction in which the first main surface 14a and the second main surface 14b of the piezoelectric layer 14 face each other. More specifically, the main surface facing direction is, for example, a direction normal to the first main surface 14a.

The acoustic reflection portion may include an acoustic reflection film such as an acoustic multilayer film to be described below. For example, the acoustic reflection film may be provided on a surface of the support.

In the present example embodiment, a center-to-center distance between a plurality of pairs of the first electrode finger 25 and the third electrode finger 27 adjacent to each other is the same as a center-to-center distance between a plurality of pairs of the second electrode finger 26 and the third electrode finger 27 adjacent to each other. Meanwhile, the center-to-center distance between the first electrode finger 25 and the third electrode finger 27 adjacent to each other and the center-to-center distance between the second electrode finger 26 and the third electrode finger 27 adjacent to each other are not constant. In this case, the longest distance between a center-to-center distance between the first electrode finger 25 and the third electrode finger 27 adjacent to each other and a center-to-center distance between the second electrode finger 26 and the third electrode finger 27 adjacent to each other is defined as p. In a case where the center-to-center distance is constant as in the present example embodiment, the center-to-center distance between any adjacent electrode fingers is also the distance p.

In a case where a thickness of the piezoelectric film is defined as d, d/p is preferably about 0.5 or less, and more preferably about 0.24 or less, for example. Therefore, the bulk wave in the thickness shear mode is suitably excited. In the present example embodiment, the thickness d is a thickness of the piezoelectric layer 14.

Meanwhile, an acoustic wave device according to an example embodiment of the present invention is not necessarily configured to use the bulk wave in the thickness shear mode. For example, the acoustic wave device according to an example embodiment of the present invention may be configured to be capable of exciting a plate wave. In this case, an excitation region is the intersecting region E illustrated in FIG. 2.

In the present example embodiment, the piezoelectric layer 14 is made of lithium niobate. In the present specification, the fact that a certain structural element or portion is made of a certain material includes a case where a trace amount of impurity is included to the extent that the electrical characteristics of the acoustic wave device do not significantly deteriorate. A fractional bandwidth of the acoustic wave device 10 depends on Euler angles (φ, θ, ψ) of lithium niobate used in the piezoelectric layer 14. The fractional bandwidth is represented by (|fa−fr|/fr)×100[%] in a case where a resonant frequency is defined as fr and an anti-resonant frequency is defined as fa.

A relationship between the fractional bandwidth of the acoustic wave device 10 and Euler angles (φ, θ, ψ) of the piezoelectric layer 14 in a case where d/p is infinitely close to 0 is derived. φ in the Euler angles is set to 0°.

FIG. 6 is a view illustrating a map of a fractional bandwidth with respect to Euler angles (0°, θ, ψ) of LiNbO₃ in a case where d/p is infinitely close to 0.

A region R indicated by hatching in FIG. 6 is a region in which at least about 2% or more of a fractional bandwidth is obtained, for example. When a range of the region R is approximated, the range is a range represented by Formula (1), Formula (2), and Formula (3) below. In a case where φ in Euler angles (φ, θ, ψ) is within a range of 0°±10°, a relationship between θ and ψ and the fractional bandwidth is the same as a relationship illustrated in FIG. 6. Even in a case where the piezoelectric layer 14 is a lithium tantalate layer, the relationship between θ and ψ in Euler angles (within a range of 0°±10°, θ, ψ) and the fractional bandwidth is the same as the relationship illustrated in FIG. 6.

$$( Within a range of 0 ° \pm 10 ° , 0 ° to 25 ° , and any ψ ) \qquad Formula ( 1 )$$

$$( Within a range of 0 ° \pm 10 ° , 25 ° to 100 ° , 0 ° to 75 {° [ ( 1 - {( θ - 50 )}^{2} / 2500 ) ]}^{1 / 2} or 180 ° - 75 {° [ ( 1 - {( θ - 50 )}^{2} / 2500 ) ]}^{1 / 2} to 180 ° ) \qquad Formula ( 2 )$$

$$( Within a range of 0 ° \pm 10 ° , 180 ° - 40 {° [ ( 1 - {( ψ - 90 )}^{2} / 8100 ) ]}^{1 / 2} to 180 ° , any ψ ) \qquad Formula ( 3 )$$

It is preferable that Euler angles are within the range of Formula (1), Formula (2), or Formula (3) described above. As a result, the fractional bandwidth can be sufficiently widened. Therefore, the acoustic wave device 10 can be suitably used in a filter device.

With reference to FIG. 3, in the first example embodiment, at a portion at which the third busbar 24 is laminated with the insulator layer 29 and the first electrode finger 25, the first electrode finger 25, the insulator layer 29, and the third busbar 24 are laminated in this order from the piezoelectric layer 14 side. Meanwhile, the order of lamination of the first electrode finger 25, the insulator layer 29, and the third busbar 24 is not limited to the above.

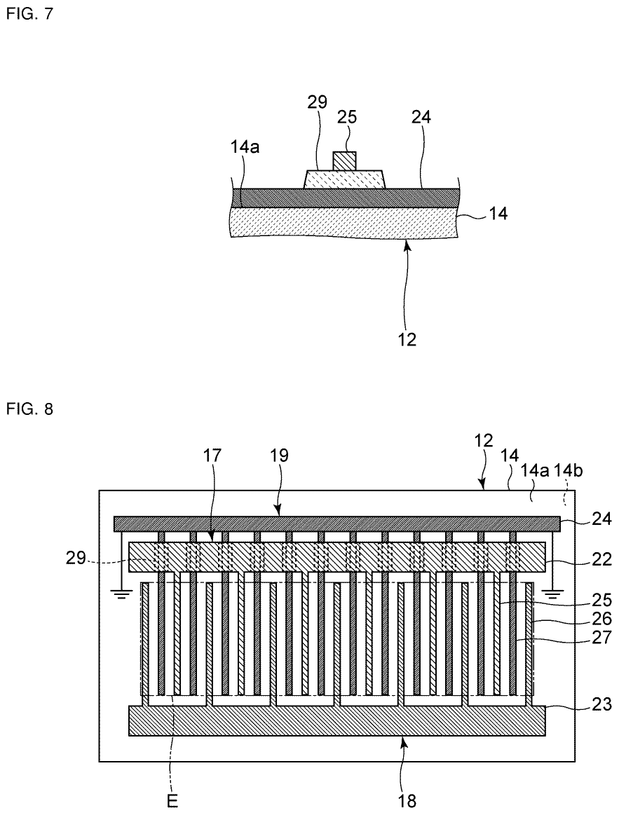

For example, in a modification example of the first example embodiment illustrated in FIG. 7, at a portion at which the third busbar 24 is laminated with the insulator layer 29 and the first electrode finger 25, the third busbar 24, the insulator layer 29, and the first electrode finger 25 are laminated in this order. More specifically, one insulator layer 29 is provided between the third busbar 24 and one first electrode finger 25.

The plurality of insulator layers 29 are provided on the third busbar 24. The plurality of insulator layers 29 are arranged side by side in the electrode finger orthogonal direction. Each of the insulator layers 29 is located between the third busbar 24 and one first electrode finger 25. Therefore, the first comb-shaped electrode and the third electrode are electrically insulated from each other.

In the present modification example as well, in the same manner as the first example embodiment, in a case where the acoustic wave device is used in a filter device, a size of the filter device can be reduced and an electrical resistance of the third electrode can be reduced.

FIG. 8 is a schematic plan view of an acoustic wave device according to a second example embodiment.

The present example embodiment is different from the first example embodiment, in positions of the first busbar 22 and the third busbar 24 and positions of the plurality of insulator layers 29. Except for the above points, the acoustic wave device according to the present example embodiment has the same configuration as the acoustic wave device 10 according to the first example embodiment.

The first busbar 22 is located between the intersecting region E and the third busbar 24. The plurality of insulator layers 29 are arranged side by side in the electrode finger orthogonal direction. Each of the insulator layers 29 is provided on the first main surface 14a of the piezoelectric layer 14 to cover a portion of one third electrode finger 27. On the other hand, the plurality of first electrode fingers 25 are not covered with the insulator layer 29. The first busbar 22 is provided on the first main surface 14a, on the plurality of insulator layers 29, and on the plurality of first electrode fingers 25.

In this manner, the first busbar 22 that is a portion of the first comb-shaped electrode 17 and the plurality of third electrode fingers 27 that are portions of the third electrode 19 intersect each other on the piezoelectric layer 14 with the insulator layer 29 interposed therebetween. Therefore, the first busbar 22 and the plurality of third electrode fingers 27 are electrically insulated from each other. On the other hand, the first busbar 22 electrically connects the plurality of first electrode fingers 25.

In the present example embodiment as well, in the same manner as the first example embodiment, in a case where the acoustic wave device is used in a filter device, a size of the filter device can be reduced and an electrical resistance of the third electrode 19 can be reduced.

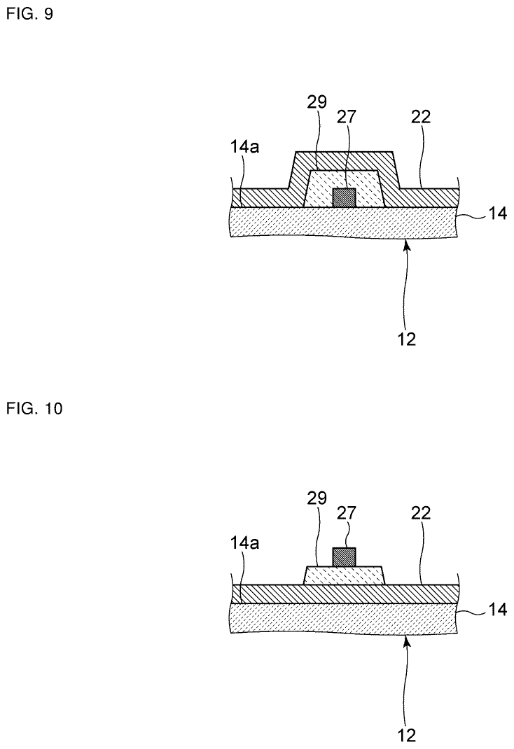

FIG. 9 is a schematic elevational cross-sectional view illustrating a vicinity of a portion at which a first busbar is laminated with an insulator layer and a third electrode finger, in the second example embodiment.

At a portion at which the first busbar 22 is laminated with the insulator layer 29 and the third electrode finger 27, the third electrode finger 27, the insulator layer 29, and the first busbar 22 are laminated in this order from the piezoelectric layer 14 side. Meanwhile, the order of lamination of the third electrode finger 27, the insulator layer 29, and the first busbar 22 is not limited to the above.

For example, in a modification example of the second example embodiment illustrated in FIG. 10, at a portion at which the first busbar 22 is laminated with the insulator layer 29 and the third electrode finger 27, the first busbar 22, the insulator layer 29, and the third electrode finger 27 are laminated in this order. More specifically, one insulator layer 29 is provided between the first busbar 22 and one third electrode finger 27.

The plurality of insulator layers 29 are provided on the first busbar 22. The plurality of insulator layers 29 are arranged side by side in the electrode finger orthogonal direction. Each of the insulator layers 29 is located between the first busbar 22 and one third electrode finger 27. Therefore, the first comb-shaped electrode and the third electrode are electrically insulated from each other.

In the present modification example as well, in the same manner as the second example embodiment, in a case where the acoustic wave device is used in a filter device, a size of the filter device can be reduced and an electrical resistance of the third electrode can be reduced.

With reference to FIG. 8, in the second example embodiment, the first comb-shaped electrode 17 is connected to an input potential. The second comb-shaped electrode 18 is connected to an output potential. Meanwhile, the first comb-shaped electrode 17 may be connected to the output potential. In this case, the second comb-shaped electrode 18 is connected to the input potential. The same applies to the modification example of the second example embodiment.

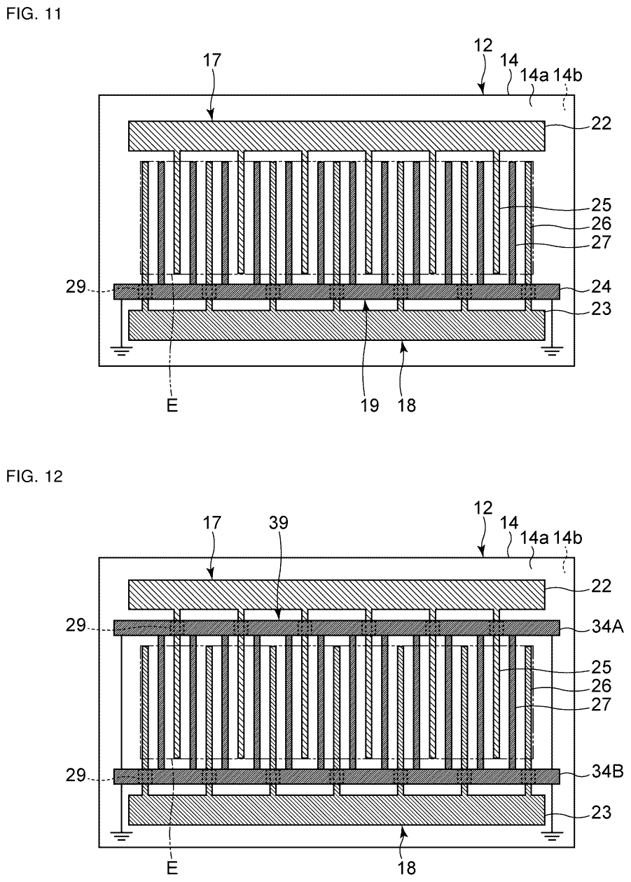

FIG. 11 is a schematic plan view of an acoustic wave device according to a third example embodiment.

The present example embodiment is different from the first example embodiment, in positions of the second busbar 23 and the third busbar 24 and positions of the plurality of insulator layers 29. Except for the above points, the acoustic wave device according to the present example embodiment has the same configuration as the acoustic wave device 10 according to the first example embodiment.

The third busbar 24 is located between the intersecting region E and the second busbar 23. The plurality of insulator layers 29 are arranged side by side in the electrode finger orthogonal direction. Each of the insulator layers 29 is provided on the first main surface 14a of the piezoelectric layer 14 to cover a portion of one second electrode finger 26. On the other hand, the plurality of third electrode fingers 27 are not covered with the insulator layer 29. The third busbar 24 is provided on the first main surface 14a, on the plurality of insulator layers 29, and on the plurality of third electrode fingers 27.

In this manner, the plurality of second electrode fingers 26 that are portions of the second comb-shaped electrode 18 and a plurality of third busbars 24 that are portions of the third electrode 19 intersect each other on the piezoelectric layer 14 with the insulator layer 29 interposed therebetween. Therefore, the third busbar 24 and the plurality of second electrode fingers 26 are electrically insulated from each other. On the other hand, the third busbar 24 electrically connects the plurality of third electrode fingers 27.

In the present example embodiment, the first comb-shaped electrode 17 is connected to an input potential. The second comb-shaped electrode 18 is connected to an output potential. Therefore, a portion of the second comb-shaped electrode 18 connected to the output potential and the plurality of third busbars 24 that are portions of the third electrode 19 intersect each other on the piezoelectric layer 14 with the insulator layer 29 interposed therebetween. The configuration of the present example embodiment corresponds to the configuration in a case where the first comb-shaped electrode 17 is connected to the output potential in the first example embodiment.

In the present example embodiment as well, in the same manner as the first example embodiment, in a case where the acoustic wave device is used in a filter device, a size of the filter device can be reduced and an electrical resistance of the third electrode 19 can be reduced.

At a portion at which the third busbar 24 is laminated with the insulator layer 29 and the second electrode finger 26, the second electrode finger 26, the insulator layer 29, and the third busbar 24 are laminated in this order from the piezoelectric layer 14 side. Meanwhile, at a portion at which the third busbar 24 is laminated with the insulator layer 29 and the second electrode finger 26, the third busbar 24, the insulator layer 29, and the second electrode finger 26 may be laminated in this order from the piezoelectric layer 14 side.

In the first to third example embodiments, the third electrode is a comb-shaped electrode. Meanwhile, the third electrode is not limited to the comb-shaped electrode. An example in which the third electrode is an electrode other than the comb-shaped electrode will be described according to a fourth example embodiment.

FIG. 12 is a schematic plan view of an acoustic wave device according to the fourth example embodiment.

The present example embodiment is different from the first example embodiment, in that a third electrode 39 includes two third busbars 34A and 34B. The third electrode 39 has a grating shape. The present example embodiment is also different from the first example embodiment, at positions of the plurality of insulator layers 29. Except for the above points, the acoustic wave device according to the present example embodiment has the same configuration as the acoustic wave device 10 according to the first example embodiment.

Each of a plurality of insulator layers 29 among all the insulator layers 29 covers a portion of one first electrode finger 25. Each of a plurality of remaining insulator layers 29 covers a portion of one second electrode finger 26.

The third busbar 34A is located between the intersecting region E and the first busbar 22. The third busbar 34A intersects the plurality of first electrode fingers 25 with the insulator layer 29 interposed therebetween. Therefore, the third busbar 34A and the plurality of first electrode fingers 25 are electrically insulated from each other. On the other hand, the third busbar 34A electrically connects the plurality of third electrode fingers 27.

The third busbar 34B is located between the intersecting region E and the second busbar 23. The third busbar 34B intersects the plurality of second electrode fingers 26 with the insulator layer 29 interposed therebetween. Therefore, the third busbar 34B and the plurality of second electrode fingers 26 are electrically insulated from each other. On the other hand, the third busbar 34B electrically connects the plurality of third electrode fingers 27.

In the present example embodiment as well, in the same manner as the first example embodiment, in a case where the acoustic wave device is used in a filter device, the filter device can be further reduced in size. In addition, the third electrode 39 has the two third busbars 34A and 34B. As a result, an electrical resistance of the third electrode 39 can be effectively reduced.

At a portion at which the third busbar 34A is laminated with the insulator layer 29 and the first electrode finger 25, the first electrode finger 25, the insulator layer 29, and the third busbar 34A are laminated in this order from the piezoelectric layer 14 side. Meanwhile, at a portion at which the third busbar 34A is laminated with the insulator layer 29 and the first electrode finger 25, the third busbar 34A, the insulator layer 29, and the first electrode finger 25 may be laminated in this order from the piezoelectric layer 14 side.

At a portion at which the third busbar 34B is laminated on the insulator layer 29 and the second electrode finger 26, the second electrode finger 26, the insulator layer 29, and the third busbar 34B are laminated in this order from the piezoelectric layer 14 side. Meanwhile, at a portion at which the third busbar 34B is laminated with the insulator layer 29 and the second electrode finger 26, the third busbar 34B, the insulator layer 29, and the second electrode finger 26 may be laminated in this order from the piezoelectric layer 14 side.

Hereinafter, first to third modification examples of the fourth example embodiment, in which only a position of each busbar and positions of the plurality of insulator layers 29 are different from those of the fourth example embodiment will be illustrated. In the first to third modification examples as well, in the same manner as the fourth example embodiment, in a case where the acoustic wave device is used in a filter device, a size of the filter device can be reduced and an electrical resistance of the third electrode 39 can be effectively reduced.

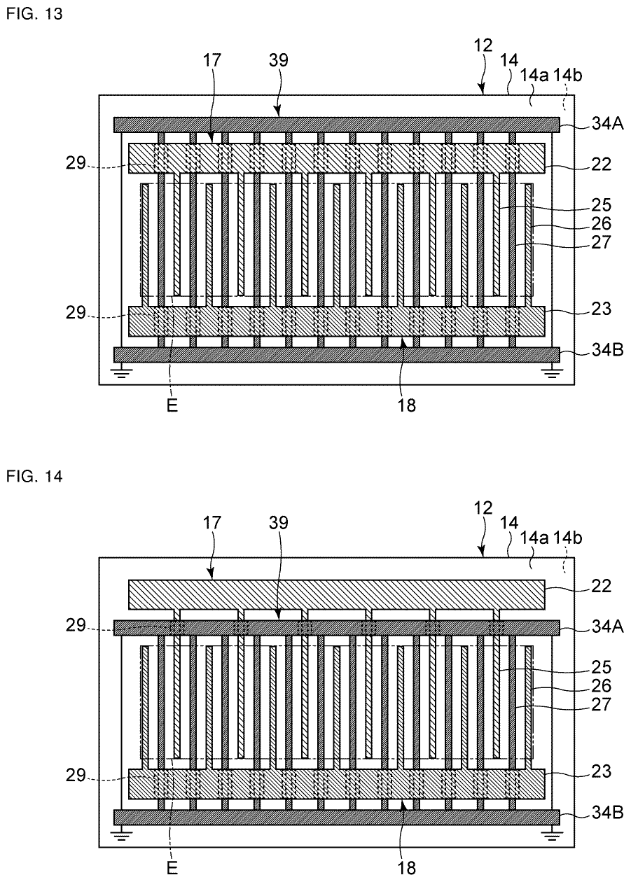

In the first modification example illustrated in FIG. 13, each of the plurality of insulator layers 29 covers a portion of one third electrode finger 27. The third busbar 34A and the third busbar 34B are located at an outer side portion of the first busbar 22 and the second busbar 23.

More specifically, the first busbar 22 is located between the intersecting region E and the third busbar 34A. The first busbar 22 intersects the plurality of third electrode fingers 27 with the insulator layer 29 interposed therebetween. The second busbar 23 is located between the intersecting region E and the third busbar 34B. The second busbar 23 intersects the plurality of third electrode fingers 27 with the insulator layer 29 interposed therebetween.

At a portion at which the first busbar 22 is laminated with the insulator layer 29 and the third electrode finger 27, the third electrode finger 27, the insulator layer 29, and the first busbar 22 are laminated in this order from the piezoelectric layer 14 side. Meanwhile, at a portion at which the first busbar 22 is laminated with the insulator layer 29 and the third electrode finger 27, the first busbar 22, the insulator layer 29, and the third electrode finger 27 may be laminated in this order from the piezoelectric layer 14 side.

At a portion at which the second busbar 23 is laminated with the insulator layer 29 and the third electrode finger 27, the third electrode finger 27, the insulator layer 29, and the second busbar 23 are laminated in this order from the piezoelectric layer 14 side. Meanwhile, at a portion at which the second busbar 23 is laminated with the insulator layer 29 and the third electrode finger 27, the second busbar 23, the insulator layer 29, and the third electrode finger 27 may be laminated in this order from the piezoelectric layer 14 side.

In the second modification example illustrated in FIG. 14, each of a plurality of insulator layers 29 among all the insulator layers 29 covers a portion of one first electrode finger 25. Each of a plurality of remaining insulator layers 29 covers a portion of one third electrode finger 27.

The third busbar 34A is located between the intersecting region E and the first busbar 22. The third busbar 34A intersects the plurality of first electrode fingers 25 with the insulator layer 29 interposed therebetween. The second busbar 23 is located between the intersecting region E and the third busbar 34B. The second busbar 23 intersects the plurality of third electrode fingers 27 with the insulator layer 29 interposed therebetween.

At a portion at which the third busbar 34A is laminated with the insulator layer 29 and the first electrode finger 25, the first electrode finger 25, the insulator layer 29, and the third busbar 24 are laminated in this order from the piezoelectric layer 14 side. Meanwhile, at a portion at which the third busbar 24 is laminated with the insulator layer 29 and the first electrode finger 25, the third busbar 34A, the insulator layer 29, and the first electrode finger 25 may be laminated in this order from the piezoelectric layer 14 side.

At a portion at which the second busbar 23 is laminated with the insulator layer 29 and the third electrode finger 27, the third electrode finger 27, the insulator layer 29, and the second busbar 23 are laminated in this order from the piezoelectric layer 14 side. Meanwhile, at a portion at which the second busbar 23 is laminated with the insulator layer 29 and the third electrode finger 27, the second busbar 23, the insulator layer 29, and the third electrode finger 27 may be laminated in this order from the piezoelectric layer 14 side.

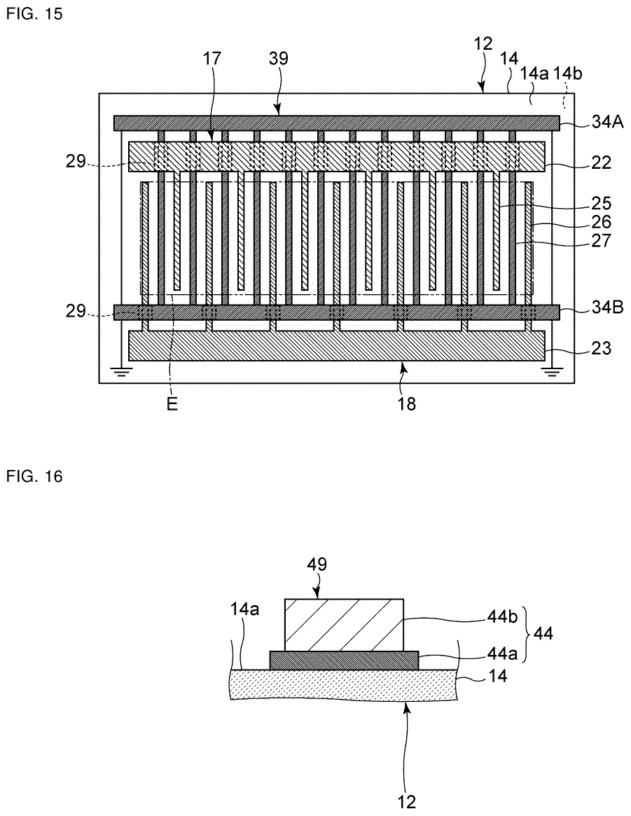

In the third modification example illustrated in FIG. 15, each of a plurality of insulator layers 29 among all the insulator layers 29 covers a portion of one third electrode finger 27. Each of a plurality of remaining insulator layers 29 covers a portion of one second electrode finger 26.

The first busbar 22 is located between the intersecting region E and the third busbar 34A. The first busbar 22 intersects the plurality of third electrode fingers 27 with the insulator layer 29 interposed therebetween. The third busbar 34B is located between the intersecting region E and the second busbar 23. The third busbar 34B intersects the plurality of second electrode fingers 26 with the insulator layer 29 interposed therebetween.

At a portion at which the first busbar 22 is laminated with the insulator layer 29 and the third electrode finger 27, the third electrode finger 27, the insulator layer 29, and the first busbar 22 are laminated in this order from the piezoelectric layer 14 side. Meanwhile, at a portion at which the first busbar 22 is laminated with the insulator layer 29 and the third electrode finger 27, the first busbar 22, the insulator layer 29, and the third electrode finger 27 may be laminated in this order from the piezoelectric layer 14 side.

At a portion at which the third busbar 34B is laminated on the insulator layer 29 and the second electrode finger 26, the second electrode finger 26, the insulator layer 29, and the third busbar 34B are laminated in this order from the piezoelectric layer 14 side. Meanwhile, at a portion at which the third busbar 34B is laminated with the insulator layer 29 and the second electrode finger 26, the third busbar 34B, the insulator layer 29, and the second electrode finger 26 may be laminated in this order from the piezoelectric layer 14 side.

In the second modification example and the third modification example, the first comb-shaped electrode 17 is connected to an input potential. The second comb-shaped electrode 18 is connected to an output potential. The configuration of the third modification example corresponds to the configuration in a case where the first comb-shaped electrode 17 is connected to the output potential and the second comb-shaped electrode 18 is connected to the input potential in the second modification example.

FIG. 16 is a schematic cross-sectional view of a third busbar in a direction orthogonal to a direction in which the third busbar extends, in a fifth example embodiment.

In the present example embodiment, a layer configuration of a third busbar 44 in a third electrode 49 is different from that of the first example embodiment. Except for the above points, the acoustic wave device according to the third example embodiment has the same configuration as the acoustic wave device 10 according to the first example embodiment.

The third busbar 44 is a multilayer body of a metal layer 44a and an auxiliary conductive layer 44b. A thickness of the auxiliary conductive layer 44b is larger than a thickness of the metal layer 44a. In the present specification, the fact that the thicknesses of the layers of the busbar or the electrode finger are different from each other means that an absolute value of a difference in thickness between the two layers is 10% or more with respect to any thickness of the two layers. In the same manner, the fact that the thickness of the busbar and the thickness of the electrode fingers are different means that an absolute value of a difference in thickness between the busbar and the electrode finger is 10% or more with respect to any thickness of the busbar and the electrode finger.

On the other hand, the third electrode finger 27 illustrated with reference to FIG. 1 includes a single-layer metal layer. The third electrode finger 27 includes the same metal layer as the metal layer 44a in the third busbar 44. That is, a material of the metal layer 44a in the third busbar 44 and a material of the metal layer of the third electrode finger 27 are the same material. In the present example embodiment, the thickness of the metal layer 44a in the third busbar 44 is the same as a thickness of the metal layer of the third electrode finger 27.

The third electrode finger 27 may include a laminated metal film. In this case, for example, in the third electrode finger 27, a Ti layer and an Al layer may be laminated in this order from the piezoelectric layer 14 side. Meanwhile, the material of the third electrode finger 27 is not limited to the above. In the same manner, the metal layer 44a of the third busbar 44 may also include a laminated metal film. In a case where the third electrode finger 27 and the metal layer 44a of the third busbar 44 include a laminated metal film, materials of the respective layers of the third electrode finger 27 and the metal layer 44a may be the same. In addition, the thicknesses of each layer of the third electrode finger 27 and the metal layer 44a may be the same.

As described above, the third busbar 44 includes the auxiliary conductive layer 44b. As a result, an electrical resistance of the third electrode 49 can be further reduced. In addition, in the present example embodiment as well, in the same manner as the first example embodiment, in a case where the acoustic wave device is used in a filter device, the filter device can be further reduced in size.

It is preferable that an electrical resistance of the material of the auxiliary conductive layer 44b is lower than an electrical resistance of the material of the metal layer 44a. As a result, an electrical resistance of the third electrode 49 can be further effectively reduced.

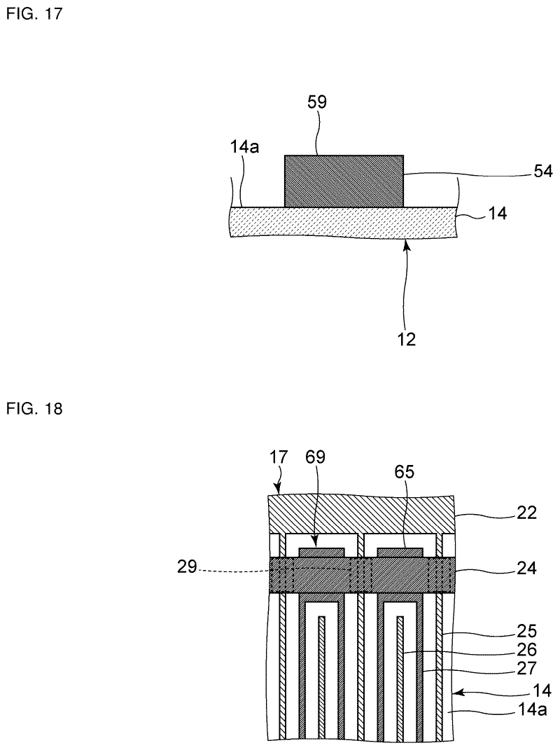

FIG. 17 is a schematic cross-sectional view of a third busbar in a direction orthogonal to a direction in which the third busbar extends, in a sixth example embodiment.

The present example embodiment is different from the first example embodiment, in that a thickness of a third busbar 54 in a third electrode 59 is different from the thickness of the third electrode finger 27. Except for the above points, the acoustic wave device according to the present example embodiment has the same configuration as the acoustic wave device 10 according to the first example embodiment.

In the third busbar 54 and the third electrode finger 27 illustrated with reference to FIG. 1, the layer configurations are the same. More specifically, in the present example embodiment, the third busbar 54 and the third electrode fingers 27 include a single-layer metal layer. Materials used for the third busbar 54 and the third electrode fingers 27 are the same. Meanwhile, the materials used for the third electrode finger 27 and the third busbar 54 may be different from each other.

The thickness of the third busbar 54 is larger than the thickness of the third electrode finger 27. As a result, an electrical resistance of the third electrode 59 can be further reduced. In addition, in the present example embodiment as well, in the same manner as the first example embodiment, in a case where the acoustic wave device is used in a filter device, the filter device can be further reduced in size.

In a case where a thickness of a portion of the third busbar 54, which is not laminated with an electrode finger is compared with the thickness of the third electrode finger 27, it is sufficient that the thickness of the third busbar 54 is larger than the thickness of the third electrode finger 27. The third electrode fingers 27 and the third busbar 54 may include a laminated metal film. In this case, a thickness obtained by adding up thicknesses of respective layers in the third busbar 54 may be larger than a thickness obtained by adding up thicknesses of the respective layers in the third electrode finger 27.

FIG. 18 is a schematic plan view illustrating a portion of a functional electrode in a seventh example embodiment.

The present example embodiment is different from the first example embodiment, in that the plurality of third electrode fingers 27 are electrically connected to each other. Except for the above points, the acoustic wave device according to the present example embodiment has the same configuration as the acoustic wave device 10 according to the first example embodiment.

The third busbar 24 in a third electrode 69 is located between an intersecting region and the first busbar 22. The plurality of insulator layers 29 are provided on the first main surface 14a of the piezoelectric layer 14 to cover a portion of each first electrode finger 25.

The third electrode 69 includes a plurality of the connection electrodes 65. Each of the connection electrodes 65 connects, among tips of the two third electrode fingers 27 adjacent to each other, tips on the first busbar 22 side. A U-shaped electrode is configured with the connection electrode 65 and the two third electrode fingers 27. The third busbar 24 is provided on the first main surface 14a of the piezoelectric layer 14, on the plurality of insulator layers 29, and on the plurality of connection electrodes 65.

The plurality of first electrode fingers 25 that are portions of the first comb-shaped electrode 17 and the third busbar 24 that is a portion of the third electrode 69 intersect each other on the piezoelectric layer 14 with the insulator layer 29 interposed therebetween. Therefore, the third busbar 24 and the plurality of first electrode fingers 25 are electrically insulated from each other. On the other hand, the third busbar 24 electrically connects the plurality of third electrode fingers 27.

The connection electrode 65 extends in the electrode finger orthogonal direction. Therefore, an area in which the connection electrode 65 and the third busbar 24 are in contact with each other is large. Therefore, a contact resistance is small between the connection electrode 65 and the third busbar 24. Therefore, an electrical resistance of the third electrode 69 can be effectively reduced. In addition, in the present example embodiment as well, in the same manner as the first example embodiment, in a case where the acoustic wave device is used in a filter device, the filter device can be further reduced in size.

The connection electrode 65 and the third electrode finger 27 include the same metal layer. As a result, the electrical resistance of the third electrode 69 can be effectively reduced without lowering productivity.

In a case where a dimension of the connection electrode 65 in the electrode finger extending direction is defined as a width of the connection electrode 65, in the present example embodiment, a width of the third busbar 24 is smaller than the width of the connection electrode 65. Meanwhile, the width of the third busbar 24 may be larger than the width of the connection electrode 65.

In the present example embodiment, the third busbar 24 includes a single-layer metal layer. The third electrode finger 27 includes a single-layer metal layer. A material of the third busbar 24 and a material of the third electrode finger 27 are different from each other. In this case, it is preferable that an electrical resistance of the material of the third busbar 24 is lower than an electrical resistance of the material of the third electrode finger 27. As a result, an electrical resistance of the third electrode 69 can be effectively reduced. Even in a case where the connection electrode 65 is provided, the third busbar 24 may include the same metal layer as the third electrode finger 27. The third busbar 24 and the third electrode finger 27 may include a laminated metal film. In this case, it is preferable that an electrical resistance of a material having the highest electrical resistance among the materials of the respective layers in the third busbar 24 is lower than an electrical resistance of a material having the highest electrical resistance among the materials of the respective layers in the third electrode finger 27. It is preferable that an electrical resistance of a material having the lowest electrical resistance among the materials of the respective layers in the third busbar 24 is lower than an electrical resistance of a material having the lowest electrical resistance among the materials of the respective layers in the third electrode finger 27. As a result, the electrical resistance of the third electrode 69 can be more reliably reduced.

A thickness of the metal layer of the third busbar 24 is larger than a thickness of the metal layer of the third electrode finger 27. As a result, the electrical resistance of the third electrode 69 can be further reduced. Meanwhile, for example, the thickness of the third busbar 24 and the thickness of the third electrode finger 27 may be the same.

In the same manner as the fifth example embodiment, the third busbar 24 may be a multilayer body of a metal layer and an auxiliary conductive layer. In this case as well, the electrical resistance of the third electrode 69 can be further reduced.

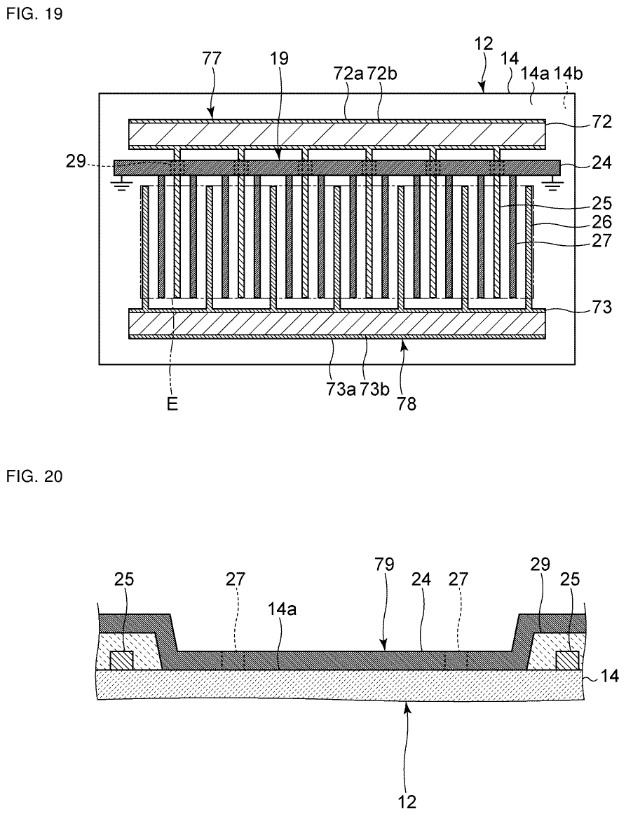

FIG. 19 is a schematic plan view of an acoustic wave device according to an eighth example embodiment.

The present example embodiment is different from the first example embodiment, in that a first busbar 72 in a first comb-shaped electrode 77 includes an auxiliary conductive layer 72b. The present example embodiment is different from the first example embodiment, in that a second busbar 73 in a second comb-shaped electrode 78 includes an auxiliary conductive layer 73b. Except for the above points, the acoustic wave device according to the present example embodiment has the same configuration as the acoustic wave device 10 according to the first example embodiment.

The first busbar 72 is a multilayer body in which a metal layer 72a and the auxiliary conductive layer 72b are laminated. A thickness of the auxiliary conductive layer 72b is larger than a thickness of the metal layer 72a.

On the other hand, the first electrode finger 25 includes a single-layer metal layer. The first electrode fingers 25 include the same metal layer as the metal layer 72a in the first busbar 72. That is, the material of the metal layer 72a in the first busbar 72 and the material of the metal layer of the first electrode fingers 25 are the same material. In the present example embodiment, the thickness of the metal layer 72a in the first busbar 72 is the same as a thickness of the metal layer of the first electrode fingers 25.

As described above, the first busbar 72 has the auxiliary conductive layer 72b. As a result, an electrical resistance of the first comb-shaped electrode 77 can be reduced. The first electrode finger 25 and the metal layer 72a in the first busbar 72 may include a laminated metal film. In this case, it is sufficient that the materials of the respective layers of the first electrode finger 25 and the metal layer 72a are the same. In addition, the thicknesses of the respective layers of the first electrode finger 25 and the metal layer 72a may be the same. Meanwhile, in an example embodiment of the present invention, at least one of the material and the thickness of each layer of the first electrode finger 25 and the metal layer 72a may be different from each other.

The second comb-shaped electrode 78 is also configured in the same manner as the first comb-shaped electrode 77. That is, the second electrode finger 26 includes a single-layer metal layer. The second busbar 73 is a multilayer body in which a metal layer 73a and the auxiliary conductive layer 73b are laminated. As a result, an electrical resistance of the second comb-shaped electrode 78 can be reduced. The second electrode finger 26 and the metal layer 73a in the second busbar 73 may include a laminated metal film. In this case, it is sufficient that the materials of the respective layers of the second electrode finger 26 and the metal layer 73a are the same. In addition, the thicknesses of the respective layers of the second electrode fingers 26 and the metal layer 73a need only be the same. Meanwhile, in the present invention, at least one of the material and the thickness of each layer in the second electrode finger 26 and the metal layer 73a may be different from each other.

In the present example embodiment as well, in the same manner as the first example embodiment, the plurality of first electrode fingers 25 and the third busbar 24 intersect each other on the piezoelectric layer 14 with the insulator layer 29 interposed therebetween. Accordingly, in a case where the acoustic wave device is used in a filter device, a size of the filter device can be reduced and an electrical resistance of the third electrode 19 can be reduced.

In the first example embodiment or the like described above, the plurality of third electrode fingers and the third busbar are laminated in the third electrode. Meanwhile, an example embodiment of the present invention is not limited thereto. An example in which a plurality of third electrode fingers and a third busbar are not laminated will be illustrated by a modification example of the eighth example embodiment.

In a third electrode 79 according to the modification example of the eighth example embodiment illustrated in FIG. 20, the plurality of third electrode fingers 27 and the third busbar 24 are not laminated. A layer of the plurality of third electrode fingers 27 and a layer of the third busbar 24 are continuously formed. Therefore, in the third electrode 79, a contact resistance is not generated between the third busbar 24 and the third electrode finger 27. Therefore, an electrical resistance of the third electrode 79 can be effectively reduced. In addition, in the same manner as the seventh example embodiment, in a case where the acoustic wave device 10 is used in a filter device, a size of the filter device can be reduced.

Hereinafter, examples of the acoustic wave device according to the eighth example embodiment and a method for manufacturing the acoustic wave device according to the modification example of the eighth example embodiment will be described.

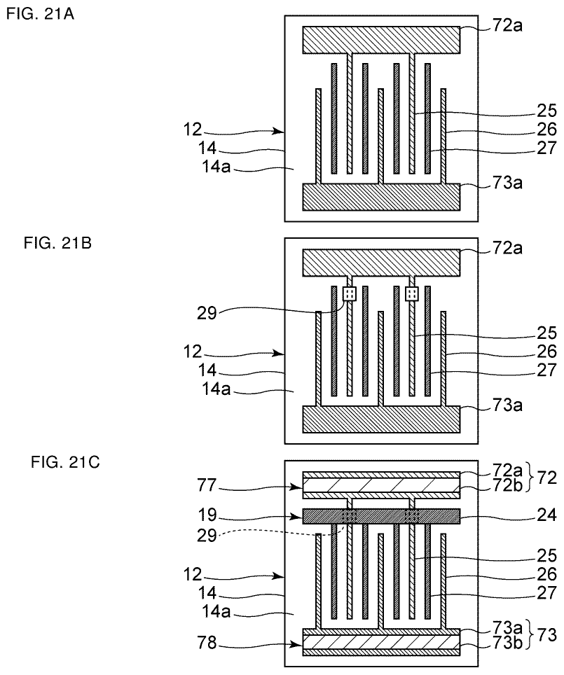

FIGS. 21A to 21C are schematic plan views for describing an example of a method for manufacturing the acoustic wave device according to the eighth example embodiment.

As illustrated in FIG. 21A, the piezoelectric substrate 12 is prepared. Next, the plurality of first electrode fingers 25, the plurality of second electrode fingers 26, and the plurality of third electrode fingers 27 are formed on the first main surface 14a of the piezoelectric layer 14 in the piezoelectric substrate 12. At the same time, the metal layer 72a and the metal layer 73a are formed on the first main surface 14a. In this case, one end of each of the plurality of first electrode fingers 25 is connected to the metal layer 72a. One end of each of the plurality of second electrode fingers 26 is connected to the metal layer 73a. The plurality of electrode fingers, the metal layer 72a, and the metal layer 73a can be formed by, for example, a vacuum vapor deposition method, a sputtering method, or the like.

Next, as illustrated in FIG. 21B, the plurality of insulator layers 29 are formed on the first main surface 14a of the piezoelectric layer 14 to cover a portion of each first electrode finger 25. More specifically, the plurality of the insulator layers 29 are formed such that one insulator layer 29 covers a portion of one first electrode finger 25. The plurality of insulator layers 29 can be formed by, for example, a vacuum vapor deposition method, a sputtering method, or the like.

Next, as illustrated in FIG. 21C, the third busbar 24, the auxiliary conductive layer 72b, and the auxiliary conductive layer 73b are simultaneously formed. More specifically, the third busbar 24 is formed over the first main surface 14a of the piezoelectric layer 14, the plurality of insulator layers 29, and the plurality of third electrode fingers 27. Therefore, the third electrode 19 is formed. The auxiliary conductive layer 72b is formed on the metal layer 72a. Therefore, the first busbar 72 is formed, and thus the first comb-shaped electrode 77 is formed. The auxiliary conductive layer 73b is formed on the metal layer 73a. Therefore, the second busbar 73 is formed, and thus the second comb-shaped electrode 78 is formed.

The third busbar 24, the auxiliary conductive layer 72b, and the auxiliary conductive layer 72b can be formed by, for example, a vacuum vapor deposition method, a sputtering method, or the like.

In this manufacturing method, a step of forming functional electrodes can be reduced by simultaneously forming the third busbar 24, the auxiliary conductive layer 72b, and the auxiliary conductive layer 73b. Accordingly, it is possible to simplify a manufacturing step of the acoustic wave device and to reduce the cost. Therefore, productivity can be improved. This manufacturing method is an example, and the method for manufacturing the acoustic wave device is not limited to the above.

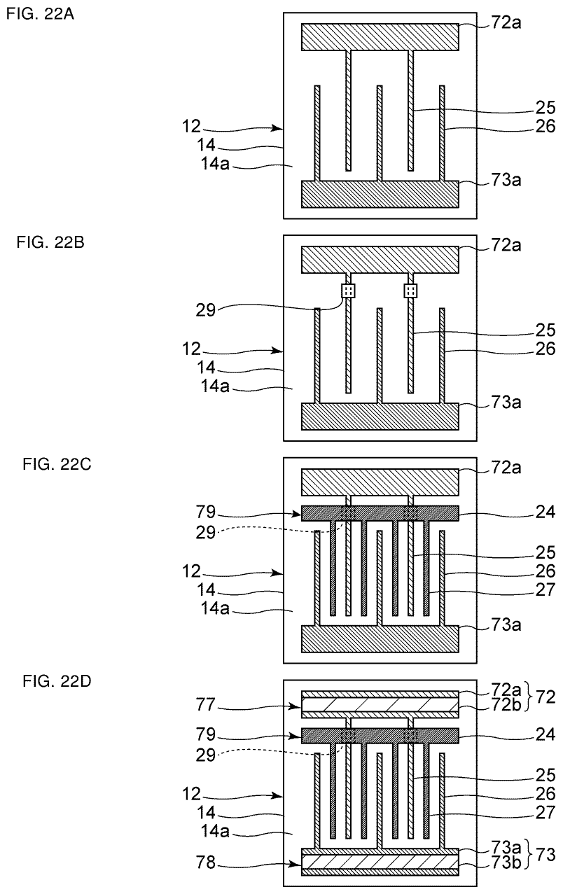

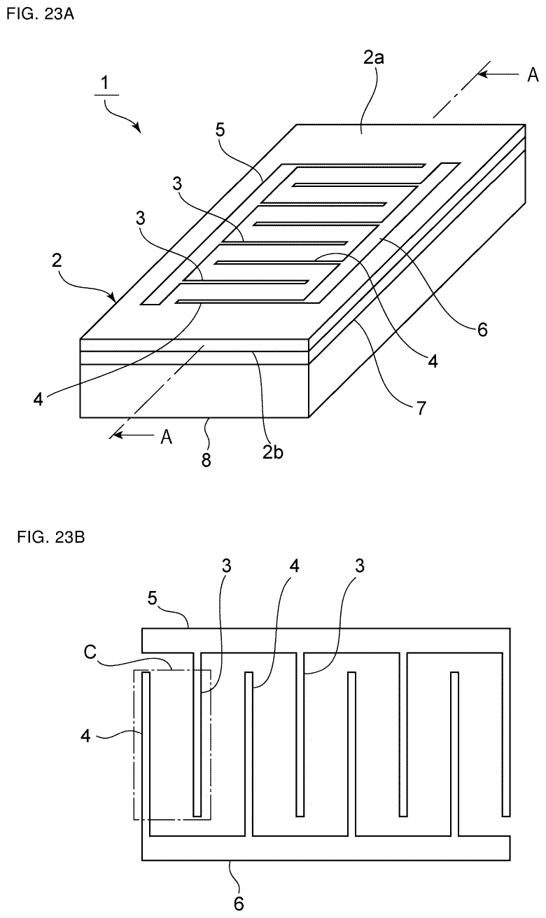

FIGS. 22A to 22D are views illustrating an example of a method for manufacturing the acoustic wave device according to the modification example of the eighth example embodiment.

As illustrated in FIG. 22A, the piezoelectric substrate 12 is prepared. Next, the plurality of first electrode fingers 25 and the plurality of second electrode fingers 26 are formed on the first main surface 14a of the piezoelectric layer 14 in the piezoelectric substrate 12. At the same time, the metal layer 72a and the metal layer 73a are formed on the first main surface 14a. In this case, one end of each of the plurality of first electrode fingers 25 is connected to the metal layer 72a. One end of each of the plurality of second electrode fingers 26 is connected to the metal layer 73a.

Next, as illustrated in FIG. 22B, the plurality of insulator layers 29 are formed on the first main surface 14a of the piezoelectric layer 14 to cover a portion of each first electrode finger 25. More specifically, the plurality of the insulator layers 29 are formed such that one insulator layer 29 covers a portion of one first electrode finger 25.

Next, as illustrated in FIG. 22C, the third electrode 79 is formed. Specifically, the plurality of third electrode fingers 27 and the third busbar 24 are formed at the same time. More specifically, the plurality of third electrode fingers 27 are formed on the first main surface 14a of the piezoelectric layer 14. The third busbar 24 is formed over the first main surface and the plurality of insulator layers 29.

Next, as illustrated in FIG. 22D, the auxiliary conductive layer 72b and the auxiliary conductive layer 73b are simultaneously formed. More specifically, the auxiliary conductive layer 72b is formed on the metal layer 72a. Therefore, the first busbar 72 is formed, and thus the first comb-shaped electrode 77 is formed. The auxiliary conductive layer 73b is formed on the metal layer 73a. Therefore, the second busbar 73 is formed, and thus the second comb-shaped electrode 78 is formed.

In this manufacturing method, the first electrode fingers 25 and the second electrode fingers 26, and the third electrode fingers 27 are formed in a separate step. Therefore, a configuration of the first electrode finger 25 and the second electrode finger 26 and a configuration of the third electrode finger 27 can be made different from each other. Therefore, the degree of freedom in design can be increased. As a result, it is easy to improve filter characteristics.

In addition, in this manufacturing method, a layer of the plurality of third electrode fingers 27 and a layer of the third busbar 24 are formed at the same time. Therefore, no contact resistance is generated between the plurality of third electrode fingers 27 and the third busbar 24. Therefore, an electrical resistance of the third electrode 79 can be effectively reduced. This manufacturing method is an example, and the method for manufacturing the acoustic wave device is not limited to the above.

Hereinafter, details of the thickness shear mode will be described by using an example in which a functional electrode is an IDT electrode. The IDT electrode does not have a third electrode finger. The “electrode” in the IDT electrode (to be described below) corresponds to the electrode finger. The support in the following example corresponds to the support substrate. Hereinafter, a reference potential may be referred to as a ground potential.

FIG. 23A is a schematic perspective view illustrating an appearance of an acoustic wave device using a bulk wave in a thickness shear mode and FIG. 23B is a plan view illustrating an electrode structure on a piezoelectric layer, and FIG. 24 is a cross-sectional view of a portion taken along a line A-A in FIG. 23A.

An acoustic wave device 1 includes a piezoelectric layer 2 made of LiNbO₃. The piezoelectric layer 2 may be made of LiTaO₃. Cut-angles of LiNbO₃ or LiTaO₃ are Z-cut, and may be a rotated Y-cut or X-cut. A thickness of the piezoelectric layer 2 is not particularly limited, and is preferably about 40 nm or larger and about 1000 nm or less, and more preferably about 50 nm or larger and about 1000 nm or less, for example, to effectively excite the thickness shear mode. The piezoelectric layer 2 has first and second main surfaces 2a and 2b facing each other. Electrode 3 and electrode 4 are provided on the first main surface 2a. Here, the electrode 3 is an example of a “first electrode”, and the electrode 4 is an example of a “second electrode”. In FIGS. 23A and 23B, a plurality of the electrodes 3 are connected to a first busbar 5. A plurality of electrodes 4 are connected to a second busbar 6. The plurality of electrodes 3 and the plurality of electrodes 4 are interdigitated with each other. The electrode 3 and the electrode 4 have a rectangular shape, and have a length direction. The electrode 3 and the electrode 4 adjacent thereto face each other in a direction orthogonal to the length direction. Both the length direction of the electrodes 3 and 4 and the direction orthogonal to the length direction of the electrodes 3 and 4 are directions intersecting the thickness direction of the piezoelectric layer 2. Therefore, it can be said that the electrode 3 and the electrode 4 adjacent thereto face each other in the direction intersecting the thickness direction of the piezoelectric layer 2. In addition, the length direction of the electrodes 3 and 4 may be changed to the direction orthogonal to the length direction of the electrodes 3 and 4 illustrated in FIGS. 23A and 23B. That is, in FIGS. 23A and 23B, the electrodes 3 and 4 may extend in a direction in which the first busbar 5 and the second busbar 6 extend. In this case, the first busbar 5 and the second busbar 6 extend in a direction in which the electrodes 3 and 4 extend in FIGS. 23A and 23B. A plurality of pairs of structures in which the electrode 3 connected to one potential and the electrode 4 connected to the other potential are adjacent to each other are provided in a direction orthogonal to the length direction of the electrodes 3 and 4. Here, a case where the electrodes 3 and 4 are adjacent to each other does not mean a case where the electrodes 3 and 4 are disposed to be in direct contact with each other, but means a case where the electrodes 3 and 4 are disposed with a distance therebetween. In addition, in a case where the electrodes 3 and 4 are adjacent to each other, the electrode connected to a hot electrode or a ground electrode, including the other electrodes 3 and 4, is not disposed between the electrodes 3 and 4. The number of pairs does not need to be integer pairs, and may be 1.5 pairs, 2.5 pairs, or the like. A center-to-center distance, that is, a pitch between the electrodes 3 and 4 is preferably in a range of about 1 μm or larger and about 10 μm or less, for example. In addition, the widths of the electrodes 3 and 4, that is, the dimensions of the electrodes 3 and 4 in the facing direction are preferably in a range of about 50 nm or larger and about 1,000 nm or less, and more preferably in a range of about 150 nm or larger and about 1,000 nm or less, for example. The center-to-center distance between the electrodes 3 and 4 is a distance connecting the center of the dimension (width dimension) of the electrode 3 in the direction orthogonal to the length direction of the electrode 3 and the center of the dimension (width dimension) of the electrode 4 in the direction orthogonal to the length direction of the electrode 4.

In addition, in the acoustic wave device 1, since the Z-cut piezoelectric layer is used, the direction orthogonal to the length direction of the electrodes 3 and 4 is a direction orthogonal to a polarization direction of the piezoelectric layer 2. This is not the case if a piezoelectric body of another cut-angle is used as the piezoelectric layer 2. Here, the description of “orthogonal” is not limited to being strictly orthogonal, and may be substantially orthogonal (an angle formed between the direction orthogonal to the length direction of the electrodes 3 and 4 and the polarization direction falls within a range of 90°±10°, for example).

A support 8 is laminated on the second main surface 2b side of the piezoelectric layer 2 with an insulating layer 7 interposed therebetween. The insulating layer 7 and the support 8 have a frame shape and have through-holes 7a and 8a as illustrated in FIG. 24. In this manner, a cavity portion 9 is provided. The cavity portion 9 enables free vibration of the excitation region C of the piezoelectric layer 2. Therefore, the support 8 is laminated on the second main surface 2b with the insulating layer 7 interposed therebetween, at a position not overlapping with the portion at which at least one pair of electrodes 3 and 4 are provided. The insulating layer 7 does not have to be provided. Therefore, the support 8 can be directly or indirectly laminated on the second main surface 2b of the piezoelectric layer 2.

The insulating layer 7 is made of silicon oxide. Meanwhile, in addition to silicon oxide, an appropriate insulating material such as silicon oxynitride or alumina can be used. The support 8 is made of Si. A plane orientation of a surface of Si on the piezoelectric layer 2 side may be (100), (110), or (111). It is desirable that Si included in the support 8 is high resistance having a resistivity of about 4 kΩcm or higher, for example. Meanwhile, the support 8 can also be made of an appropriate insulating material or semiconductor material.

Examples of the material of the support 8 include piezoelectric bodies such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, or forsterite, dielectrics such as diamond or glass, or semiconductors such as gallium nitride.

The plurality of electrodes 3 and 4 and the first and second busbars 5 and 6 are made of appropriate metals or alloys such as Al or AlCu alloys. In the acoustic wave device 1, the electrodes 3 and 4 and the first and second busbars 5 and 6 have a structure in which an Al film is laminated on a Ti film. An adhesion layer other than the Ti film may be used.

During driving, the AC voltage is applied between the plurality of electrodes 3 and the plurality of electrodes 4. More specifically, the alternating current voltage is applied between the first busbar 5 and the second busbar 6. In this manner, it is possible to obtain the resonance characteristics using the bulk wave in the thickness shear mode excited in the piezoelectric layer 2. In addition, in the acoustic wave device 1, in a case where the thickness of the piezoelectric layer 2 is defined as d and the center-to-center distance between any electrodes 3 and 4 adjacent to each other in the plurality of pairs of electrodes 3 and 4 is defined as p, d/p is about 0.5 or less, for example. In this manner, the bulk wave in the thickness shear mode is effectively excited, and satisfactory resonance characteristics can be obtained. More preferably, d/p is about 0.24 or less, for example, and in this case, more satisfactory resonance characteristics can be obtained.

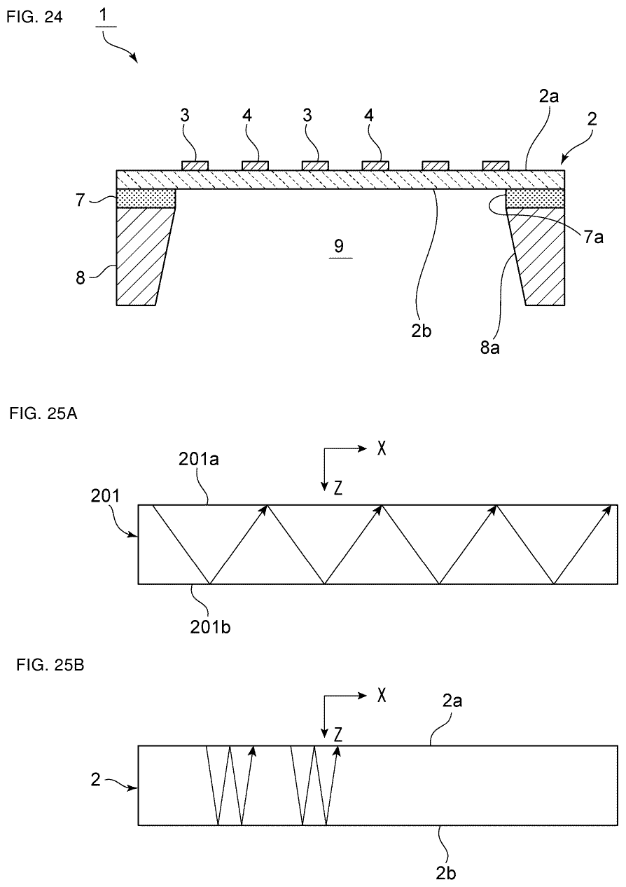

In the acoustic wave device 1, since the configuration described above is provided, even in a case where the number of pairs of the electrodes 3 and 4 is reduced in order to reduce the size, the Q factor is unlikely to be decreased. The reason is that a propagation loss is small even when the number of electrode fingers in reflectors on both sides is reduced. In addition, the number of electrode fingers can be reduced by using the bulk wave in the thickness shear mode. A difference between a Lamb wave used in the acoustic wave device and a bulk wave in the thickness shear mode will be described with reference to FIGS. 25A and 25B.

FIG. 25A is a schematic elevational cross-sectional view illustrating the Lamb wave that propagates through the piezoelectric film of the acoustic wave device as disclosed in Japanese Unexamined Patent Application Publication No. 2012-257019. Here, the wave propagates in a piezoelectric film 201 as indicated by arrows. Here, in the piezoelectric film 201, a first main surface 201a and a second main surface 201b face each other, and the thickness direction connecting the first main surface 201a and the second main surface 201b is a Z-direction. An X-direction is a direction in which the electrode fingers of the IDT electrodes are arranged side by side. As illustrated in FIG. 25A, in the Lamb wave, the wave propagates in the X-direction as illustrated in the figure. Since the wave is a plate wave, the piezoelectric film 201 vibrates as a whole. Since the wave propagates in the X-direction, the reflectors are disposed on both sides to obtain the resonance characteristics. Therefore, the propagation loss of the wave occurs, and the Q factor is decreased in a case where a size reduction is attempted, that is, in a case where the number of pairs of the electrode fingers is decreased.

On the other hand, as illustrated in FIG. 25B, in the acoustic wave device 1, since the vibration displacement is a thickness shear direction, the wave substantially propagates and resonates in the direction connecting the first main surface 2a and the second main surface 2b of the piezoelectric layer 2, that is, the Z-direction. That is, an X-direction component of the wave is significantly smaller than a Z-direction component. Since the resonance characteristics are obtained by the propagation of the wave in the Z-direction, the propagation loss is less likely to occur even when the number of the electrode fingers of the reflector is reduced. Further, even in a case where the number of pairs of the electrode pair including the electrodes 3 and 4 is reduced when the size reduction is attempted, the Q factor is unlikely to be decreased.

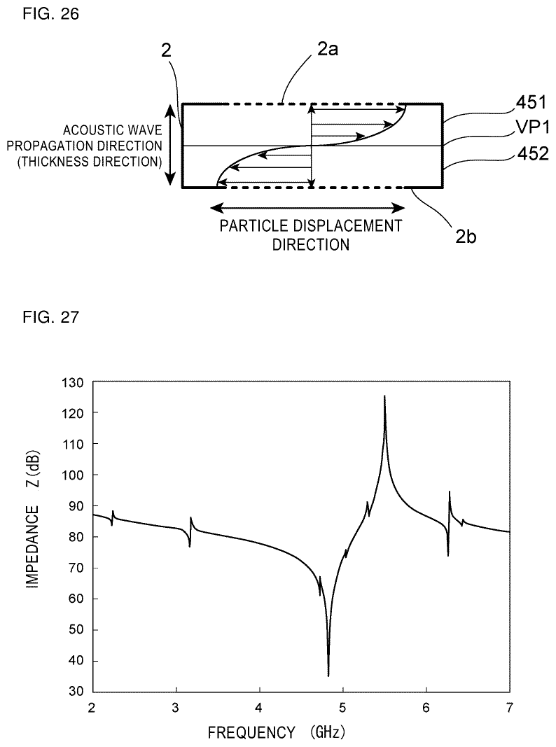

Amplitude directions of the bulk waves of the thickness shear mode are opposite to each other between a first region 451 included in the excitation region C of the piezoelectric layer 2 and a second region 452 included in the excitation region C, as illustrated in FIG. 26. FIG. 26 schematically illustrates the bulk waves in a case where the voltage is applied between the electrodes 3 and 4 such that the potential of the electrode 4 is higher than the potential of the electrode 3. The first region 451 is a region of the excitation region C between a virtual plane VP1, which is orthogonal to the thickness direction of the piezoelectric layer 2 and bisects the piezoelectric layer 2, and the first main surface 2a. The second region 452 is a region of the excitation region C between the virtual plane VP1 and the second main surface 2b.

As described above, in the acoustic wave device 1, although at least one pair of electrodes including the electrodes 3 and 4 are disposed, the waves are not propagated in the X-direction, and thus the number of pairs of the electrode pair including the electrodes 3 and 4 does not have to be plural. That is, at least one pair of electrodes may be provided.

For example, the electrode 3 is an electrode connected to a hot potential and the electrode 4 is an electrode connected to a ground potential. Meanwhile, the electrode 3 may be connected to the ground potential and the electrode 4 may be connected to the hot potential. In the acoustic wave device 1, at least one pair of electrodes are the electrodes connected to the hot potential or the electrodes connected to the ground potential, as described above, and no floating electrodes are provided.

FIG. 27 is a view illustrating the resonance characteristics of the acoustic wave device illustrated in FIG. 24. Non-limiting examples of design parameters of the acoustic wave device 1 with the resonance characteristics are as follows.

Piezoelectric layer 2: LiNbO₃ with Euler angles (0°, 0°, 90°), thickness=400 nm.

When viewed in the direction orthogonal to the length direction of the electrodes 3 and 4, the length of the region in which the electrodes 3 and 4 overlap with each other, that is, the length of the excitation region C=40 μm, the number of pairs of the electrodes including the electrodes 3 and 4=21 pairs, the center-to-center distance between the electrodes=3 μm, the width of the electrodes 3 and 4=500 nm, and d/p=0.133.

Insulating layer 7: silicon oxide film having the thickness of 1 μm.

Support 8: Si.

The length of the excitation region C is the dimension in the length direction of the electrodes 3 and 4 of the excitation region C.

In the acoustic wave device 1, an electrode-to-electrode distance of the electrode pair including the electrodes 3 and 4 is made equal in all the plurality of pairs. That is, the electrodes 3 and 4 are disposed at regular pitches.

As is clear from FIG. 27, good resonance characteristics with the fractional bandwidth of about 12.5% are obtained despite there being no reflectors, for example.

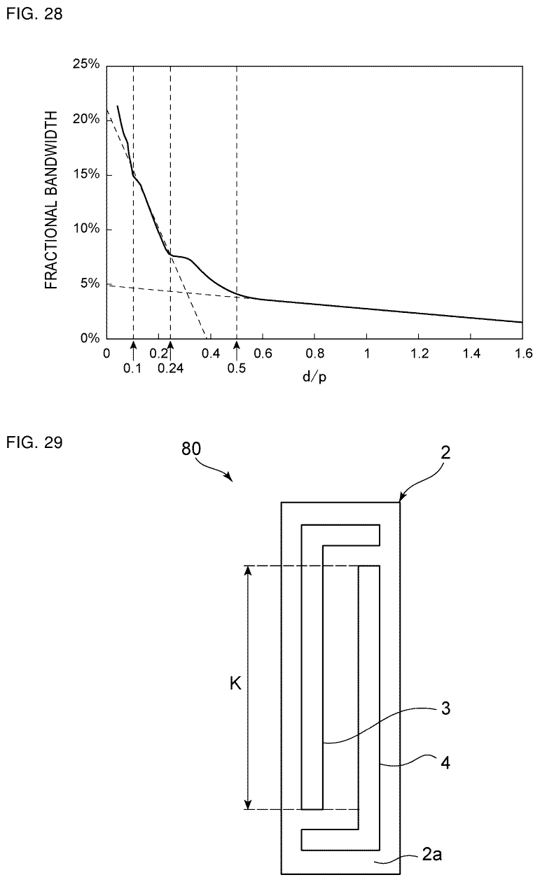

In a case where the thickness of the piezoelectric layer 2 is defined as d and the center-to-center distance of the electrodes 3 and 4 is defined as p, in the acoustic wave device 1, as described above, d/p is about 0.5 or less, for example, more preferably about 0.24 or less, for example. The description thereof will be made with reference to FIG. 28.

A plurality of acoustic wave devices are obtained by changing d/p in the same manner as the acoustic wave device that obtains the resonance characteristics illustrated in FIG. 27. FIG. 28 is a view illustrating a relationship between d/p and the fractional bandwidth as the resonator of the acoustic wave device.

As is clear from FIG. 28, when d/p>about 0.5, the fractional bandwidth is less than about 5% even in a case where d/p is adjusted, for example. On the other hand, in a case where d/p≤about 0.5, when d/p is changed within this range, the fractional bandwidth of about 5% or more can be obtained, for example, that is, the resonator having a high coupling coefficient can be formed. In addition, in a case where d/p is about 0.24 or less, the fractional bandwidth can be increased to about 7% or larger, for example. In addition, when d/p is adjusted within this range, a resonator having a wider fractional bandwidth can be obtained, and a resonator having a higher coupling coefficient can be realized. Therefore, it can be understood that, by adjusting d/p to about 0.5 or less, for example, it is possible to configure a resonator having a high coupling coefficient using the bulk wave in the thickness shear mode.

FIG. 29 is a plan view of the acoustic wave device using the bulk wave in the thickness shear mode. In an acoustic wave device 80, the pair of electrodes including the electrode 3 and electrode 4 are provided on the first main surface 2a of the piezoelectric layer 2. K in FIG. 29 is an intersecting width. As described above, in the acoustic wave device according to an example embodiment of the present invention, the number of pairs of the electrodes may be one pair. In this case as well, when d/p is about 0.5 or less, for example, it is possible to effectively excite the bulk wave in the thickness shear mode.

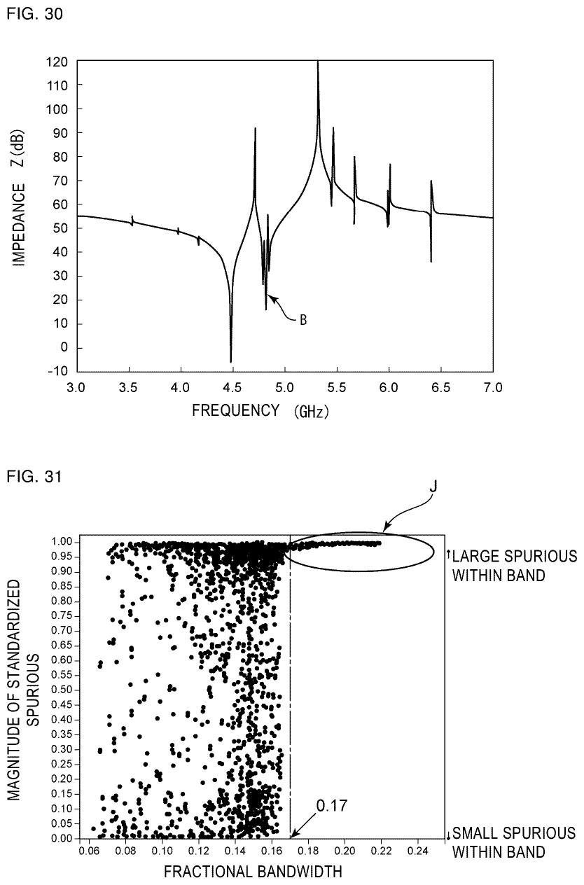

In the acoustic wave device 1, preferably, it is desirable that the metallization ratio MR of any adjacent electrodes 3 and 4 in the plurality of electrodes 3 and 4 to the excitation region C, which is the region in which the adjacent electrodes 3 and 4 overlap with each other when viewed in the facing direction, satisfies MR≤about 1.75 (d/p)+0.075, for example. In this case, the spurious can be effectively reduced. The description thereof will be made with reference to FIGS. 30 and 31. FIG. 30 is a reference view illustrating an example of the resonance characteristics of the acoustic wave device 1. The spurious indicated by an arrow B appears between the resonant frequency and the anti-resonant frequency. d/p=about 0.08 and the Euler angles of LiNbO₃ are (0°, 0°, 90°), for example. In addition, the metallization ratio MR is about 0.35, for example.

The metallization ratio MR will be described with reference to FIG. 23B. In the electrode structure in FIG. 23B, it is assumed that, when focusing on the pair of electrodes 3 and 4, only the pair of electrodes 3 and 4 are provided. In this case, a portion surrounded by a one-dot chain line is the excitation region C. The excitation region C is a region that overlaps with the electrode 4 in the electrode 3 when the electrode 3 and the electrode 4 are viewed in the direction orthogonal to the length direction of the electrodes 3 and 4, that is, in the facing direction, a region that overlaps with the electrode 3 in the electrode 4, and a region in which the electrode 3 and the electrode 4 overlap with each other in the region between the electrode 3 and the electrode 4. An area of the electrodes 3 and 4 inside the excitation region C with respect to an area of the excitation region C is the metallization ratio MR. That is, the metallization ratio MR is a ratio of an area of the metallization portion to the area of the excitation region C.

In a case where the plurality of pairs of electrodes are provided, MR may be a ratio of the metallization portion included in the entire excitation region to a total area of the excitation region.

FIG. 31 is a view illustrating a relationship between the fractional bandwidth and a phase rotation amount of the impedance of the spurious standardized at 180 degrees as a magnitude of the spurious when a large number of acoustic wave resonators are formed in accordance with the configuration of the acoustic wave device 1. The fractional bandwidth is adjusted by changing a film thickness of the piezoelectric layer and the dimensions of the electrodes. In addition, FIG. 31 illustrates the results in a case where the piezoelectric layer made of the Z-cut LiNbO₃ is used, and the same tendency is obtained in a case where piezoelectric layers with other cut-angles are used.

In a region surrounded by an ellipse J in FIG. 31, the spurious is as large as about 1.0, for example. As is clear from FIG. 31, in a case where the fractional bandwidth exceeds about 0.17, that is, exceeds about 17%, for example, a large spurious with a spurious level of 1 or more appears in a pass band even when the parameters of the fractional bandwidth are changed. That is, as in the resonance characteristics illustrated in FIG. 30, a large spurious indicated by an arrow B appears within the band. Therefore, the fractional bandwidth is preferably about 17% or less, for example. In this case, by adjusting the film thickness of the piezoelectric layer 2, the dimensions of the electrodes 3 and 4, or the like, the spurious can be reduced.

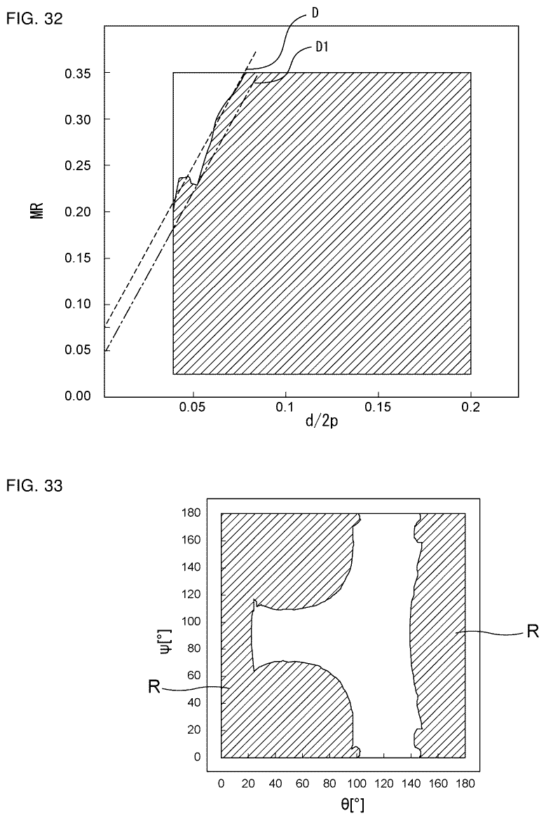

FIG. 32 is a view illustrating a relationship between d/2p, the metallization ratio MR, and the fractional bandwidth. In the acoustic wave device described above, various acoustic wave devices having different d/2p and MR are configured, and the fractional bandwidth is measured. A hatched portion on a right side of a broken line D in FIG. 32 is a region in which the fractional bandwidth is about 17% or less, for example. A boundary between the hatched region and a non-hatched region is expressed by MR=about 3.5 (d/2p)+0.075, for example. That is, MR=about 1.75 (d/p)+0.075, for example. Therefore, preferably, MR≤about 1.75 (d/p)+0.075, for example. In this case, it is easy to set the fractional bandwidth to about 17% or less, for example. A region on a right side of MR=about 3.5 (d/2p)+0.05, for example, indicated by a one-dot chain line D1 in FIG. 32 is more preferable. That is, when MR≤about 1.75 (d/p)+0.05, the fractional bandwidth can be reliably set to about 17% or less, for example.

FIG. 33 is a view illustrating a map of a fractional bandwidth with respect to Euler angles (0°, θ, Ψ) of LiNbO₃ in a case where d/p is infinitely close to 0. Each of a plurality of regions R illustrated in FIG. 33 with hatching is a region in which a fractional bandwidth of about 2% or more is obtained, for example. In a case where o in Euler angles (φ, θ, ψ) is within a range of about 0°±5°, for example, a relationship between θ and ψ and the fractional bandwidth is the same as the relationship illustrated in FIG. 33. In a case where a piezoelectric layer is made of lithium tantalate (LiTaO₃) as well, the relationship between θ and ψ in Euler angles (in a range of 0°±5°, θ, ψ) and BW is the same as the relationship illustrated in FIG. 33.

Therefore, in a case where o of the Euler angles (φ, θ, ψ) of lithium niobate or lithium tantalate of the piezoelectric layer is within a range of 0°±5° and θ and φ are within a range of any of a plurality of regions R illustrated in FIG. 33, the fractional bandwidth can be sufficiently widened, which is preferable.

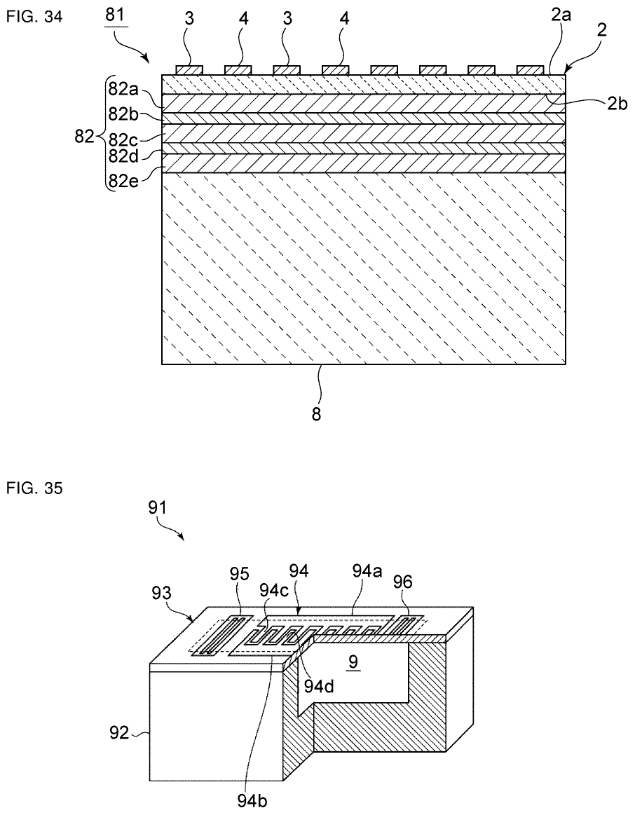

FIG. 34 is an elevational cross-sectional view of an acoustic wave device including an acoustic multilayer film. In an acoustic wave device 81, an acoustic multilayer film 82 is laminated on the second main surface 2b of the piezoelectric layer 2. The acoustic multilayer film 82 has a multilayer structure of low acoustic impedance layers 82a, 82c, and 82e having a relatively low acoustic impedance and high acoustic impedance layers 82b and 82d having a relatively high acoustic impedance. In a case where the acoustic multilayer film 82 is used, the bulk wave in the thickness shear mode can be confined in the piezoelectric layer 2 without using the cavity portion 9 in the acoustic wave device 1. In the acoustic wave device 81 as well, the resonance characteristics based on the bulk wave in the thickness shear mode can be obtained by setting d/p to about 0.5 or less, for example. In the acoustic multilayer film 82, the number of laminated layers of the low acoustic impedance layers 82a, 82c, and 82e and the high acoustic impedance layers 82b and 82d is not particularly limited. At least one layer of the high acoustic impedance layers 82b and 82d may be disposed on a side farther from the piezoelectric layer 2 than the low acoustic impedance layers 82a, 82c, and 82e.

The low acoustic impedance layers 82a, 82c, and 82e and the high acoustic impedance layers 82b and 82d described above can be made of appropriate material as long as the relationship of the acoustic impedance described above is satisfied. Examples of the materials of the low acoustic impedance layers 82a, 82c, and 82e include silicon oxide, silicon oxynitride, or the like. In addition, examples of the materials of the high acoustic impedance layers 82b and 82d include alumina, silicon nitride, metal, or the like.

FIG. 35 is a perspective view of a partial notch for describing an acoustic wave device using a Lamb wave.

An acoustic wave device 91 includes a support substrate 92. The support substrate 92 is provided with a recess portion that is open on an upper surface. A piezoelectric layer 93 is laminated on the support substrate 92. As a result, the cavity portion 9 is provided. An IDT electrode 94 is provided on the piezoelectric layer 93 above the cavity portion 9. Reflectors 95 and 96 are provided on both sides of the IDT electrode 94 in an acoustic wave propagation direction. In FIG. 35, an outer periphery of the cavity portion 9 is indicated by broken lines. Here, the IDT electrode 94 includes first and second busbars 94a and 94b, a plurality of first electrode fingers 94c, and a plurality of second electrode fingers 94d. The plurality of first electrode fingers 94c are connected to the first busbar 94a. The plurality of second electrode fingers 94d are connected to the second busbar 94b. The plurality of first electrode fingers 94c and the plurality f second electrode fingers 94d are interdigitated with each other.

In the acoustic wave device 91, the Lamb wave as the plate wave is excited by applying an alternating current electric field to the IDT electrodes 94 on the cavity portion 9. Since the reflectors 95 and 96 are provided on both sides, the resonance characteristics caused by the Lamb wave can be obtained.

In this manner, an acoustic wave device according to an example embodiment of the present invention may use the plate wave. In the example illustrated in FIG. 35, the IDT electrode 94, the reflector 95, and the reflector 96 are provided on a main surface corresponding to the first main surface 14a of the piezoelectric layer 14 illustrated in FIG. 1 or the like. On the other hand, in an acoustic wave device according to an example embodiment of the present invention, the pair of comb-shaped electrodes and the plurality of third electrode fingers are provided on the first main surface 14a. In a case where the acoustic wave device according to an example embodiment of the present invention uses the plate wave, on the first main surface 14a of the piezoelectric layer 14 in the first to eighth example embodiments and each of the modification examples, a pair of comb-shaped electrodes, a plurality of third electrode fingers, and the reflector 95 and the 96 may be provided. In this case, the pair of comb-reflector shaped electrodes and the plurality of third electrode fingers may be interposed between the reflector 95 and the reflector 96 in the electrode finger orthogonal direction.

In the acoustic wave devices according to the first to eighth example embodiments and each of the modification examples, for example, the acoustic multilayer film 82 illustrated in FIG. 34 may be provided as an acoustic reflection film between a support and a piezoelectric layer as a piezoelectric film. Specifically, the support and the piezoelectric film may be disposed such that at least a portion of the support and at least a portion of the piezoelectric film face each other with the acoustic multilayer film 82 interposed therebetween. In this case, in the acoustic multilayer film 82, the low acoustic impedance layer and the high acoustic impedance layer may be alternately laminated. The acoustic multilayer film 82 may be the acoustic reflection portion in the acoustic wave device.

In the acoustic wave devices according to the first to eighth example embodiments and each of the modification examples which use the bulk wave in the thickness shear mode, as described above, d/p is preferably about 0.5 or less, and is more preferably about 0.24 or less, for example. As a result, better resonance characteristics can be obtained.

Further, in the excitation regions in the acoustic wave devices according to the first to eighth example embodiments and each of the modification examples which use the bulk wave in the thickness shear mode, as described above, MR≤about 1.75 (d/p)+0.075 is preferably satisfied, for example. More specifically, it is preferable that, in a case where a metallization ratio of the first electrode finger and the third electrode finger, and the second electrode finger and the third electrode finger, with respect to the excitation region is defined as MR, MR≤about 1.75 (d/p)+0.075 is satisfied, for example. In this case, it is possible to more reliably suppress the spurious.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric film that includes a piezoelectric layer including a piezoelectric body;
a first comb-shaped electrode that is provided on the piezoelectric layer and includes a first busbar and a plurality of first electrode fingers each including one end connected to the first busbar;
a second comb-shaped electrode that is provided on the piezoelectric layer and includes a second busbar and a plurality of second electrode fingers each including one end connected to the second busbar and interdigitated with the plurality of first electrode fingers;
a third electrode that includes a plurality of third electrode fingers each provided on the piezoelectric layer to be arranged side by side with the first electrode fingers and the second electrode fingers, in plan view in a direction in which the first electrode fingers and the second electrode fingers are arranged side by side, and at least one third busbar which connects the third electrode fingers adjacent to each other, the third electrode being connected to a potential different from a potential of the first comb-shaped electrode and a potential of the second comb-shaped electrode; and
an insulator layer on the piezoelectric layer; wherein
one of the first comb-shaped electrode and the second comb-shaped electrode is connected to an input potential, and an other of the first comb-shaped electrode and the second comb-shaped electrode is connected to an output potential;
an order in which a first electrode finger among the first electrode fingers, a second electrode finger among the second electrode fingers, and a third electrode finger among the third electrode fingers are arranged side by side is an order in which the first electrode finger, the third electrode finger, the second electrode finger, and the third electrode finger are set as one period in a case where the order is started from the first electrode finger; and
at least one of a portion of the first comb-shaped electrode and a portion of the third electrode, and a portion of the second comb-shaped electrode and a portion of the third electrode intersects each other on the piezoelectric layer with the insulator layer interposed therebetween.

2. The acoustic wave device according to claim 1, wherein
when a direction orthogonal to a direction in which the first electrode finger, the second electrode finger, and the third electrode finger extend is defined as an electrode finger orthogonal direction, a region in which the first electrode finger and the second electrode finger overlap with each other in the electrode finger orthogonal direction is an intersecting region;
the at least one third busbar of the third electrode is a third busbar; and
the third busbar is located between the intersecting region and the first busbar, and the third busbar intersects the plurality of first electrode fingers with the insulator layer interposed therebetween.

3. The acoustic wave device according to claim 1, wherein
when a direction orthogonal to a direction in which the first electrode finger, the second electrode finger, and the third electrode finger extend is defined as an electrode finger orthogonal direction, a region in which the first electrode finger and the second electrode finger overlap with each other in the electrode finger orthogonal direction is an intersecting region;
the at least one third busbar of the third electrode is a third busbar; and
the first busbar is located between the intersecting region and the third busbar, and the first busbar intersects the plurality of third electrode fingers with the insulator layer interposed therebetween.

4. The acoustic wave device according to claim 1, wherein
when a direction orthogonal to a direction in which the first electrode finger, the second electrode finger, and the third electrode finger extend is defined as an electrode finger orthogonal direction, a region in which the first electrode finger and the second electrode finger overlap with each other in the electrode finger orthogonal direction is an intersecting region;
the at least one third busbar of the third electrode is two third busbars; and
one of the third busbars is located between the intersecting region and the first busbar and the third busbar intersects the plurality of first electrode fingers with the insulator layer interposed therebetween and an other of the third busbars is located between the intersecting region and the second busbar and the other third busbar intersects the plurality of second electrode fingers with the insulator layer interposed therebetween.

5. The acoustic wave device according to claim 1, wherein
when a direction orthogonal to a direction in which the first electrode finger, the second electrode finger, and the third electrode finger extend is defined as an electrode finger orthogonal direction, a region in which the first electrode finger and the second electrode finger overlap with each other in the electrode finger orthogonal direction is an intersecting region;
the at least one third busbar of the third electrode is two third busbars; and
one of the third busbars is located between the intersecting region and the first busbar and the third busbar intersects the plurality of first electrode fingers with the insulator layer interposed therebetween, and the second busbar is located between the intersecting region and an other of the third busbars and the second busbar intersects the plurality of third electrode fingers with the insulator layer interposed therebetween.

6. The acoustic wave device according to claim 1, wherein
when a direction orthogonal to a direction in which the first electrode finger, the second electrode finger, and the third electrode finger extend is defined as an electrode finger orthogonal direction, a region in which the first electrode finger and the second electrode finger overlap with each other in the electrode finger orthogonal direction is an intersecting region;
the at least one third busbar of the third electrode is two third busbars; and
the first busbar is located between the intersecting region and one of the third busbars and the first busbar intersects the plurality of third electrode fingers with the insulator layer interposed therebetween, and the second busbar is located between the intersecting region and an other of the third busbars and the second busbar intersects the plurality of third electrode fingers with the insulator layer interposed therebetween.

7. The acoustic wave device according to claim 2, wherein the third busbar, the insulator layer, and the first electrode finger are laminated in this order, from the piezoelectric layer side, at a portion at which the third busbar is laminated with the insulator layer and the first electrode finger.

8. The acoustic wave device according to claim 2, wherein the first electrode finger, the insulator layer, and the third busbar are laminated in this order, from the piezoelectric layer side, at a portion at which the third busbar is laminated with the insulator layer and the first electrode finger.

9. The acoustic wave device according to claim 3, wherein the first busbar, the insulator layer, and the third electrode finger are laminated in this order, from the piezoelectric layer side, at a portion at which the first busbar is laminated with the insulator layer and the third electrode finger.

10. The acoustic wave device according to claim 3, wherein the third electrode finger, the insulator layer, and the first busbar are laminated in this order, from the piezoelectric layer side, at a portion at which the first busbar is laminated with the insulator layer and the third electrode finger.

11. The acoustic wave device according to claim 1, wherein a thickness of the third busbar is larger than a thickness of the third electrode finger.

12. The acoustic wave device according to claim 11, wherein the third busbar is a multilayer body in which a metal layer and an auxiliary conductive layer are laminated, the metal layer including a same material as a material of the third electrode finger and having a same thickness as a thickness of the third electrode finger, the auxiliary conductive layer having a thickness larger than the thickness of the metal layer.

13. The acoustic wave device according to claim 11, wherein the third busbar includes a metal layer having a thickness larger than the thickness of the third electrode finger.

14. The acoustic wave device according to claim 2, wherein
the third busbar includes a metal layer having a thickness larger than a thickness of the third electrode finger;
the third electrode includes a plurality of connection electrodes which connect, among tips of two of the third electrode fingers adjacent to each other, tips on a first busbar side; and
the plurality of connection electrodes and the third busbar are laminated.

15. The acoustic wave device according to claim 1, wherein the first comb-shaped electrode is connected to the input potential, and the second comb-shaped electrode is connected to the output potential.

16. The acoustic wave device according to claim 1, wherein the first comb-shaped electrode is connected to the output potential, and the second comb-shaped electrode is connected to the input potential.

17. The acoustic wave device according to claim 1, wherein the acoustic wave device is structured to generate a bulk wave in a thickness shear mode.

18. The acoustic wave device according to claim 1, further comprising:
a support that is laminated on the piezoelectric film; wherein
in plan view in a lamination direction of the support and the piezoelectric film, an acoustic reflection portion is at a position of the support at which the acoustic reflection portion overlaps with the plurality of first electrode fingers, the plurality of second electrode fingers, and the plurality of third electrode fingers; and
in a case where a longest distance is defined as p among a center-to-center distance between the first electrode finger and the third electrode finger adjacent to each other and a center-to-center distance between the second electrode finger and the third electrode finger adjacent to each other and a thickness of the piezoelectric film is defined as d, d/p is about 0.5 or less.

19. The acoustic wave device according to claim 18, wherein d/p is about 0.24 or less.

20. The acoustic wave device according to claim 18, wherein the acoustic reflection portion includes a cavity, and the support and the piezoelectric film are positioned such that a portion of the support and a portion of the piezoelectric film face each other with the cavity portion interposed therebetween.

21. The acoustic wave device according to claim 18, wherein the acoustic reflection portion includes an acoustic reflection film including a high acoustic impedance layer having a relatively high acoustic impedance and a low acoustic impedance layer having a relatively low acoustic impedance, and the support and the piezoelectric film are positioned such that at least a portion of the support and at least a portion of the piezoelectric film face each other with the acoustic reflection film interposed therebetween.

22. The acoustic wave device according to claim 18, wherein
when a direction orthogonal to a direction in which the first electrode finger, the second electrode finger, and the third electrode finger extend is defined as an electrode finger orthogonal direction, a region in which the first electrode finger and the third electrode finger adjacent to each other overlap with each other in the electrode finger orthogonal direction and which is a region between centers of the first electrode finger and the third electrode finger adjacent to each other, and a region in which the second electrode finger and the third electrode finger adjacent to each other overlap with each other in the electrode finger orthogonal direction and which is a region between centers of the second electrode finger and the third electrode finger adjacent to each other are each an excitation region; and
when a metallization ratio of the first electrode finger and the third electrode finger, and the second electrode finger and the third electrode finger, with respect to the excitation region is defined as MR, MR≤about 1.75 (d/p)+0.075 is satisfied.

23. The acoustic wave device according to claim 1, wherein
the piezoelectric layer is made of lithium niobate; and
Euler angles (φ, θ, ψ) of the lithium niobate of the piezoelectric layer are in a range of Formula (1), Formula (2), or Formula (3):
$$( 0 ° \pm 10 ° range , 0 ° to 25 ° , any ψ ) \qquad Formula ( 1 )$$
$$( 0 ° \pm 10 ° range , 25 ° to 100 ° , 0 ° to 75 {° [ ( 1 - {( θ - 50 )}^{2} / 2500 ) ]}^{1 / 2} or 180 ° - 75 {° [ ( 1 - {( θ - 50 )}^{2} / 2500 ) ]}^{1 / 2} to 180 ° ) \qquad Formula ( 2 )$$
$$( 0 ° \pm 10 ° range , 180 ° - 40 {° [ ( 1 - {( ψ - 90 )}^{2} / 8100 ) ]}^{1 / 2} to 180 ° , any ψ ) . \qquad Formula ( 3 )$$
